(19) United States
(12) Patent Application Publication
(10) Pub. No.: US 2025/0098522 A1
(43) Pub. Date: Mar. 20, 2025

(54) EMISSIVE MATERIAL, LIGHT-EMITTING DIODE, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Mingfeng Tan, Beijing (CN); Xuan Li, Beijing (CN); Tongzhi Liu, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/576,660

(22) PCT Filed: Dec. 5, 2022
(86) PCT No.: PCT/CN2022/136520

§ 371 Date: Jan. 4, 2024

(51) Int. Cl. H10K 85/60

(52) U.S. Cl. CPC H10K 85/631; H10K 85/623; H10K 85/656; H10K 85/6572

(57) ABSTRACT

An emissive material is provided. The emissive material has a molecular structure formula of (D)m-(A)q-(D)m′. D stands for a donor moiety of a molecule of the emissive material configured as an electron donating part of the molecule upon excitation, D being a part of the molecule where at least one occupied orbital of the molecule is distributed. A stands for an acceptor part of the molecule of the emissive material configured as an electron accepting part of the molecule upon excitation, A being a part of the molecule where at least one unoccupied orbital of the molecule is distributed. m and m′ are positive integers greater than 0. q is a positive integer greater than 1.

### TECHNICAL FIELD

The present invention relates to display technology, more particularly, to an emissive material, a light-emitting diode, and a display apparatus.

### BACKGROUND

Thermally activated delayed fluorescence (TADF) is a fluorescence emitted by a molecular species in a non-emitting excited state that can incorporate surrounding thermal energy to change states and then undergo a radiative decay process. The TADF process involves the conversion of a triplet excited state to a singlet excited state by reverse inter-system scramble (RISC) by activation. The singlet excited state emits fluorescence during de-activation to the ground state. Along with fluorescent and phosphorescent compounds, TADF compounds are one of the three main emissive materials used in organic light-emitting diodes (OLEDs).

### SUMMARY

In one aspect, the present disclosure provides an emissive material, having a molecular structure formula of (D)m-(A)q-(D)m′; wherein D stands for a donor moiety of a molecule of the emissive material configured as an electron donating part of the molecule upon excitation, D being a part of the molecule where at least one occupied orbital of the molecule is distributed; A stands for an acceptor moiety of the molecule of the emissive material configured as an electron accepting part of the molecule upon excitation, A being a part of the molecule where at least one unoccupied orbital of the molecule is distributed; m and m′ are positive integers greater than 0; and q is a positive integer greater than 1.

Optionally, the emissive material has a molecular structure formula of D1-dA-D2; D1 stands for a first donor moiety, D2 stands for a second donor moiety; dA comprises a first acceptor moiety and a second acceptor moiety; and the first acceptor moiety and the second acceptor moiety are covalently linked to each other.

Optionally, the emissive material has a molecular structure formula of D1-A1-L-A2-D2; D1 stands for a first donor moiety; D2 stands for a second donor moiety; A1 stands for a first acceptor moiety; A2 stands for a second acceptor moiety; and L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, or substituted or unsubstituted heteroarylene, and n is an integer equal to or greater than 0.

Optionally, L is a substituted or unsubstituted arylene.

Optionally, L is selected from the group consisting of:

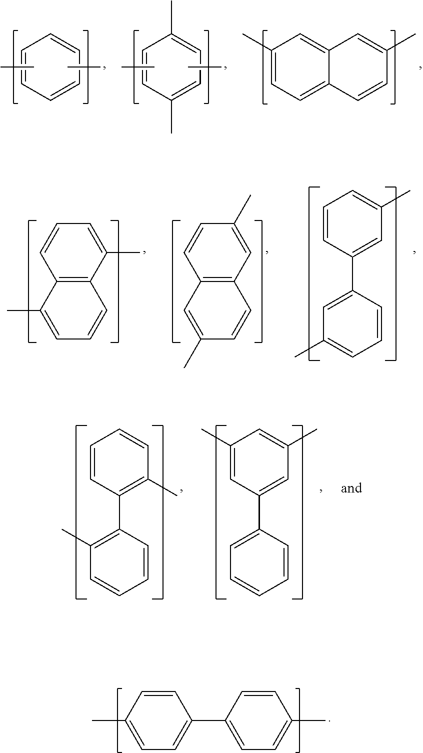

Optionally, the emissive material has a molecular structure formula of D1-[A1′-cfg-A2′]-D2; D1 stands for the first donor moiety; D2 stands for the second donor moiety; A1′-cfg stands for the first acceptor moiety; cfg-A2′ stands for the second acceptor moiety; and the first acceptor moiety and the second acceptor moiety share a common functional group cfg.

Optionally, the common functional group cfg is a functional group comprising a conjugated diene or a conjugated polyene.

Optionally, the first acceptor moiety or the second acceptor moiety comprises a phenanthro-azole moiety.

Optionally, the emissive material has a molecular structure formula of:

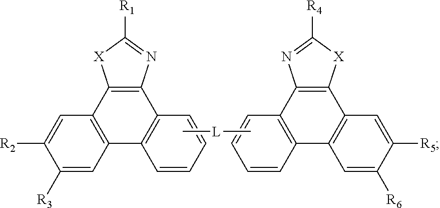

wherein X is —NH—, —O—, —S—, or N—R₀; R₀, R₁, R₄ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, or substituted or unsubstituted heteroarylene; at least one of R₂ and R₃ is a donor moiety; and at least one of R₅ and R₆ is a donor moiety.

Optionally, one of R₂ and R₃ is a donor moiety; the other one of R₂ and R₃ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; one of R₅ and R₆ is a donor moiety; and the other one of R₅ and R₆ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

Optionally, at least one of R₂ and R₃ is a first aromatic amine group; and at least one of R₅ and R₆ is a second aromatic amine group.

Optionally, the first aromatic amine group and the second aromatic amine group are independently:

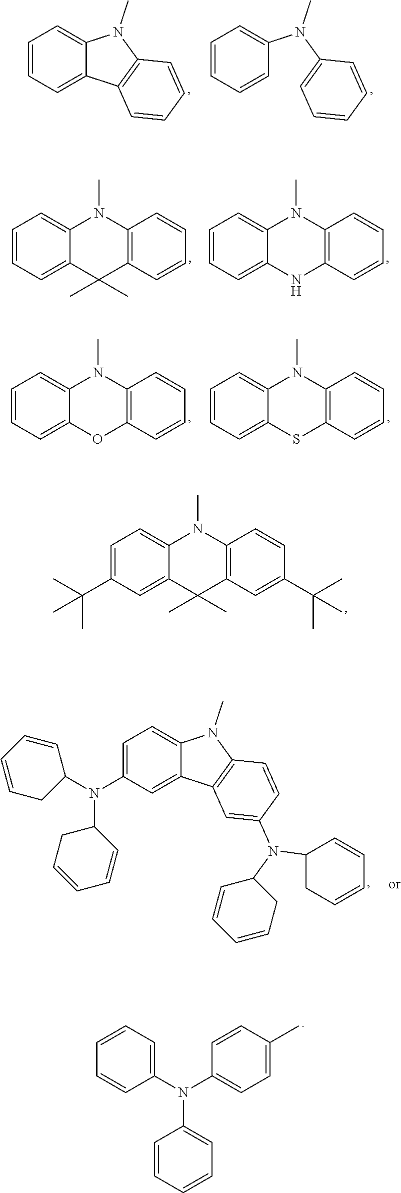

Optionally L is a single bond; and the emissive material has a molecular structure formula of:

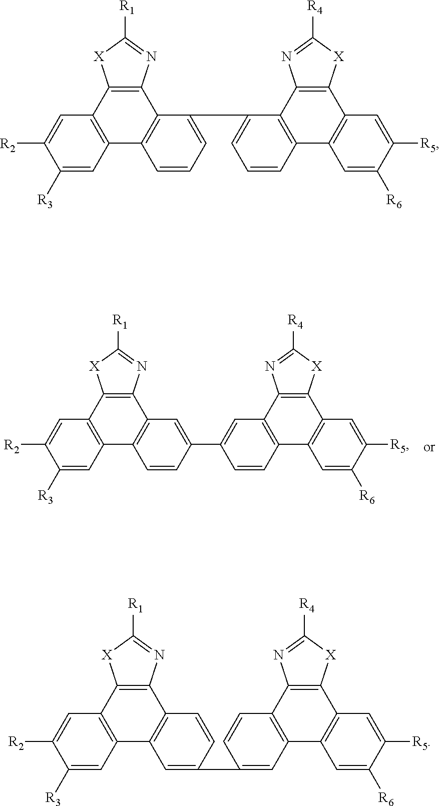

Optionally, the emissive material has a molecular structure formula of:

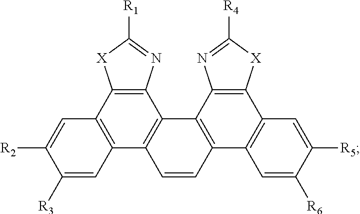

wherein X is —NH—, —S—, —S—, or N—R₀; R₀, R₁, R₄ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; at least one of R₂ and R₃ is a donor moiety; and at least one of R₅ and R₆ is a donor moiety.

Optionally, one of R₂ and R₃ is a donor moiety; the other one of R₂ and R₃ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl; one of R₅ and R₆ is a donor moiety; and the other one of R₅ and R₆ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

Optionally, at least one of R₂ and R₃ is a first aromatic amine group; and at least one of R₅ and R₆ is a second aromatic amine group.

Optionally, the first aromatic amine group and the second aromatic amine group are independently.

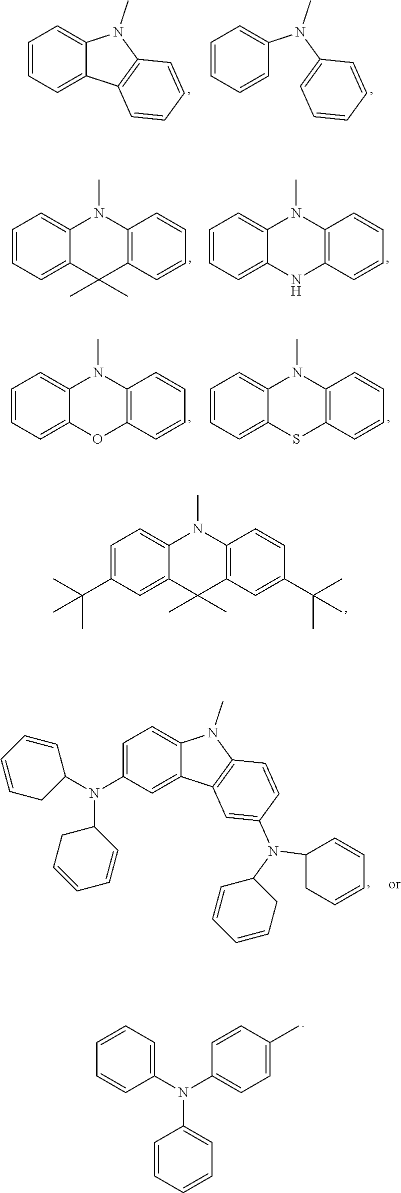

Optionally, the emissive material is selected from the group consisting of:

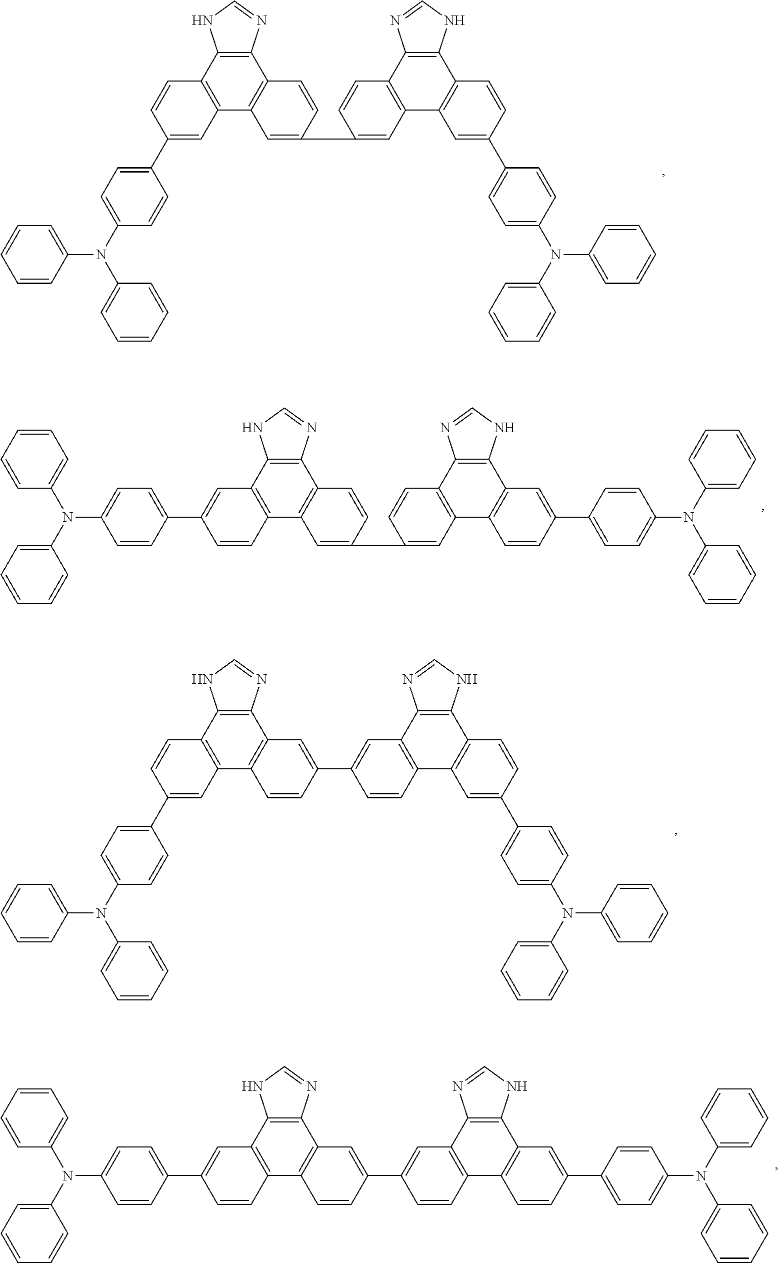

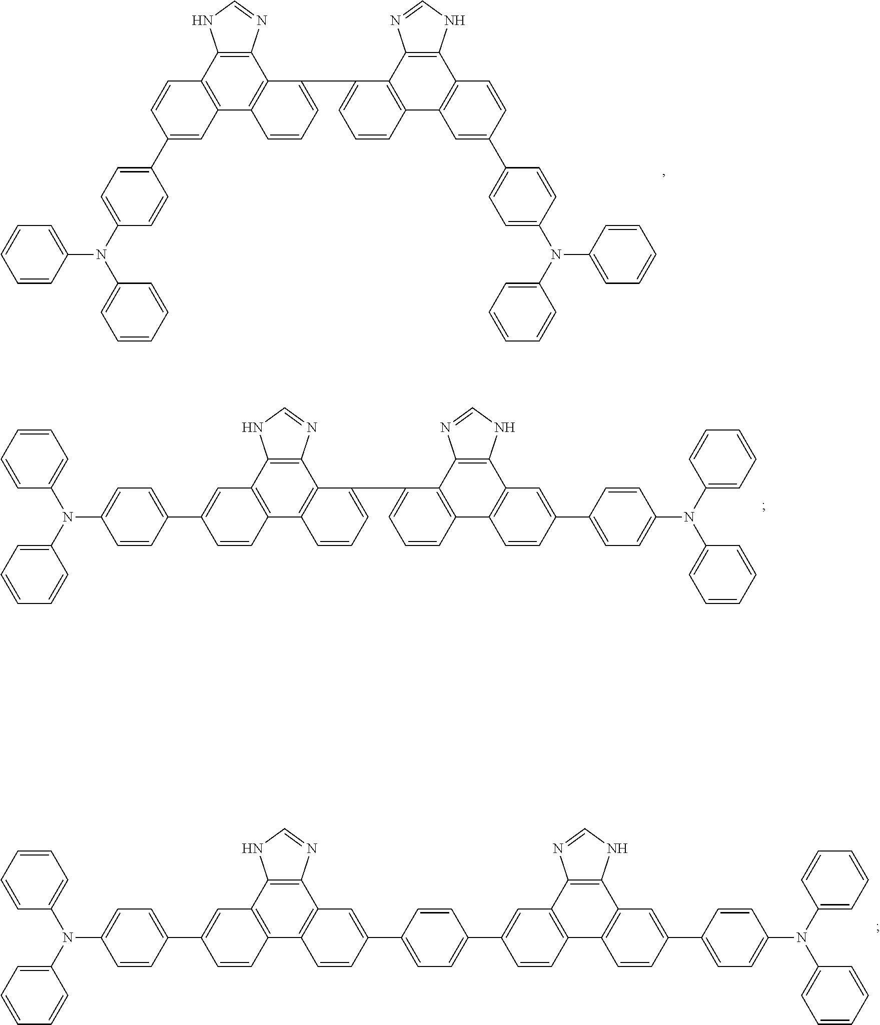 [SMILES: c1ccc(N(c2ccccc2)c2ccc(-c3ccc4c(c3)c3cccc(-c5cccc6c7cc(-c8ccc(N(c9ccccc9)c9ccccc9)cc8)ccc7c7[nH]cnc7c56)c3c3nc[nH]c43)cc2)cc1 ; c1ccc(N(c2ccccc2)c2ccc(-c3ccc4c(c3)c3[nH]cnc3c3c(-c5cccc6c7ccc(-c8ccc(N(c9ccccc9)c9ccccc9)cc8)cc7c7[nH]cnc7c56)cccc43)cc2)cc1 ; c1ccc(N(c2ccccc2)c2ccc(-c3ccc4c5ccc(-c6ccc(-c7ccc8c9ccc(-c%10ccc(N(c%11ccccc%11)c%11ccccc%11)cc%10)cc9c9[nH]cnc9c8c7)cc6)cc5c5nc[nH]c5c4c3)cc2)cc1]

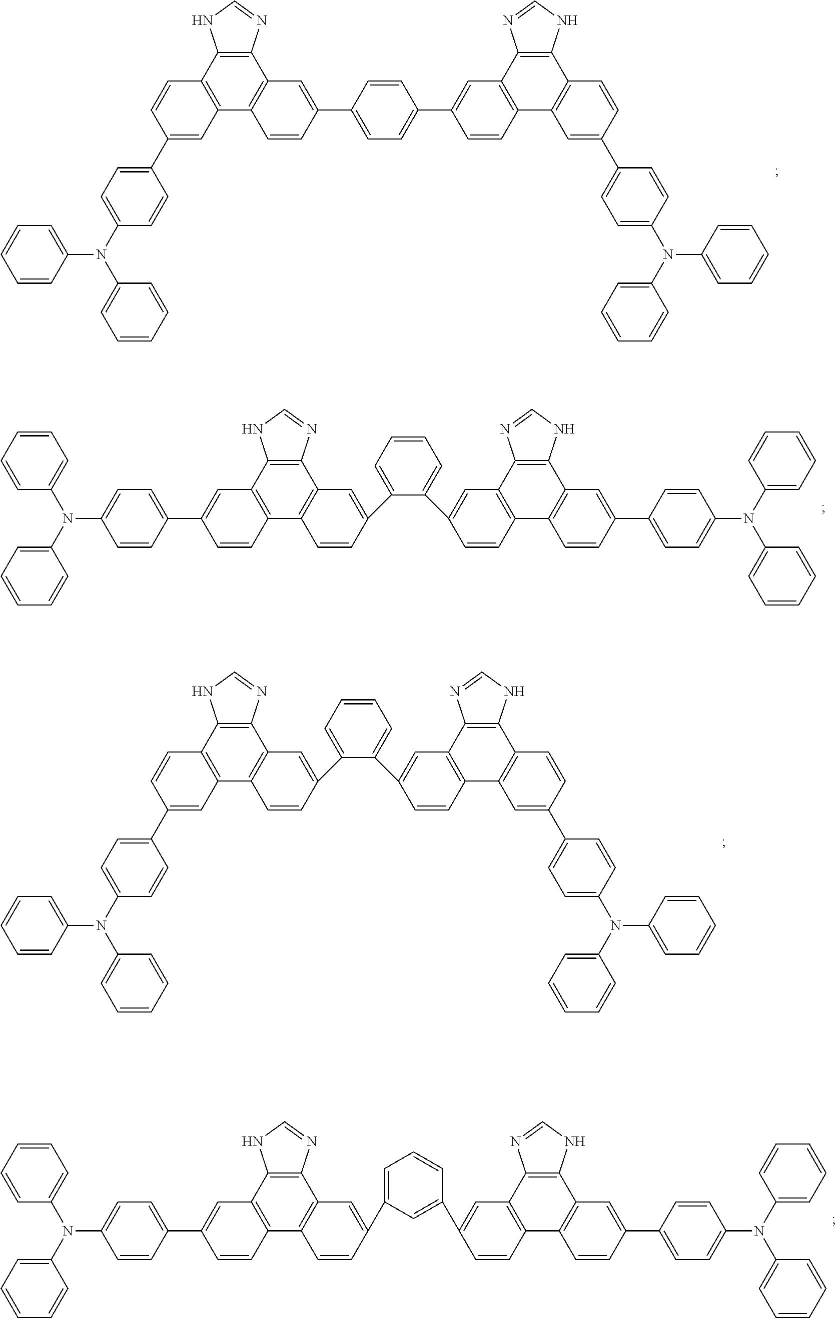

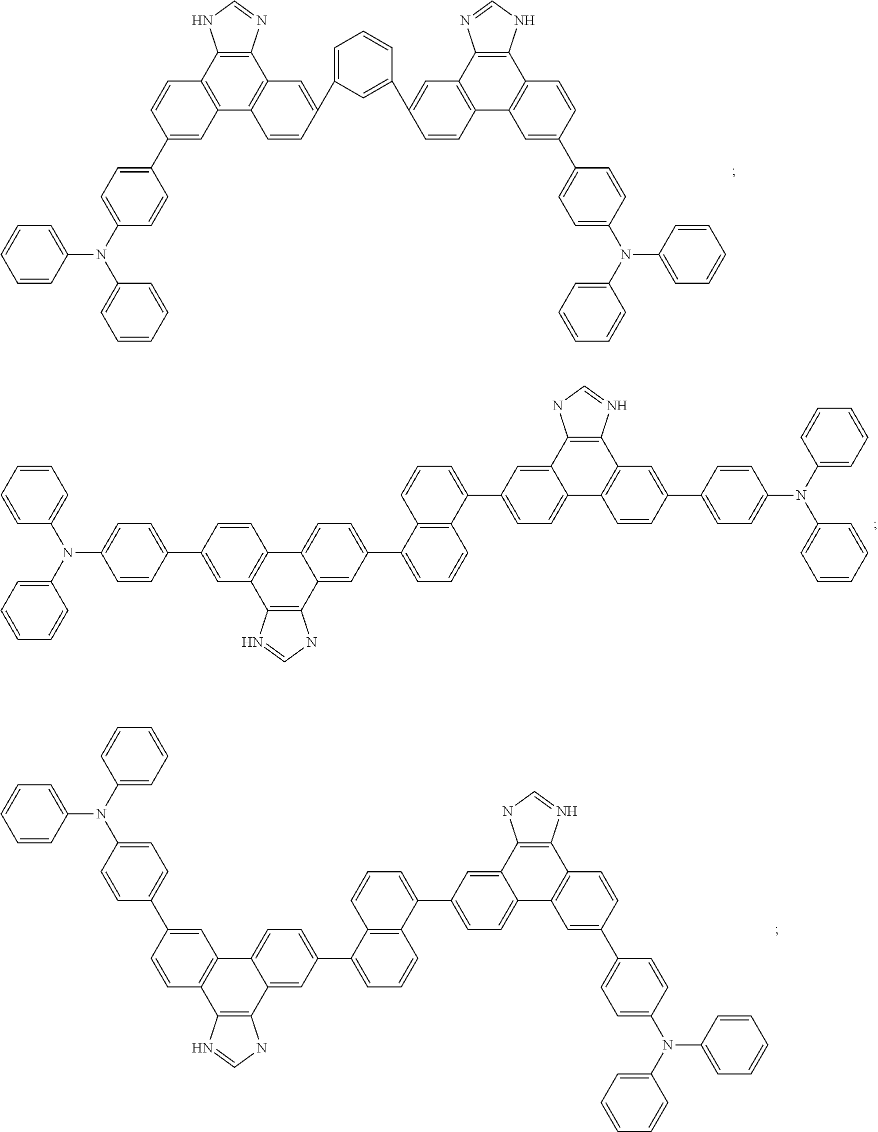

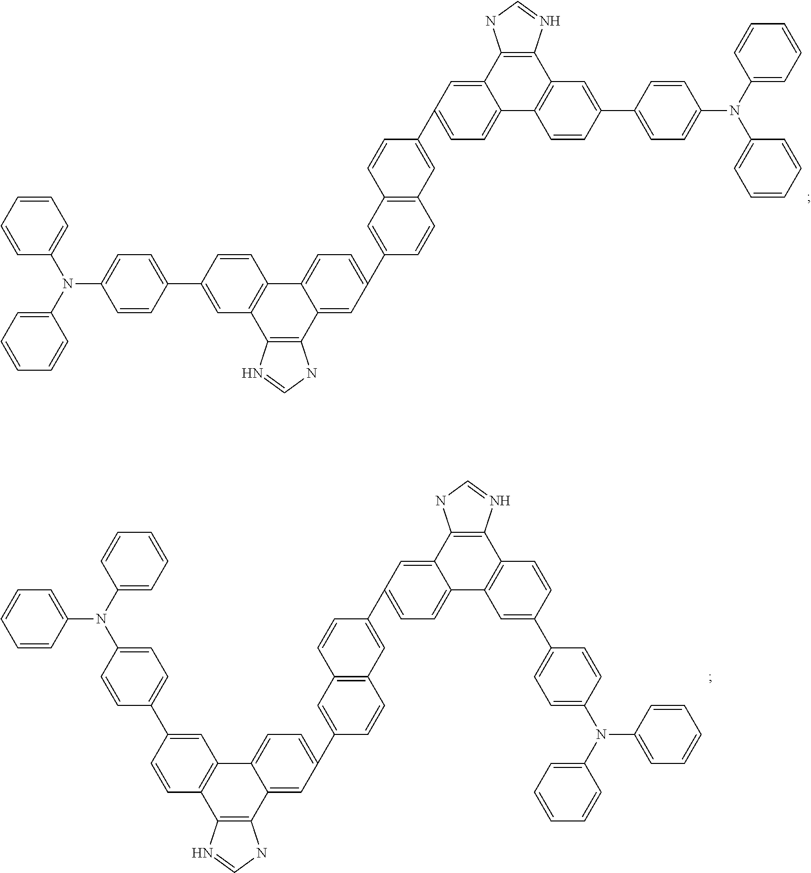 [SMILES: c1ccc(N(c2ccccc2)c2ccc(-c3ccc4c5ccc(-c6ccc7cc(-c8ccc9c%10ccc(-c%11ccc(N(c%12ccccc%12)c%12ccccc%12)cc%11)cc%10c%10nc[nH]c%10c9c8)ccc7c6)cc5c5[nH]cnc5c4c3)cc2)cc1 ; c1ccc(N(c2ccccc2)c2ccc(-c3ccc4c(c3)c3ccc(-c5ccc6cc(-c7ccc8c9cc(-c%10ccc(N(c%11ccccc%11)c%11ccccc%11)cc%10)ccc9c9nc[nH]c9c8c7)ccc6c5)cc3c3[nH]cnc43)cc2)cc1]

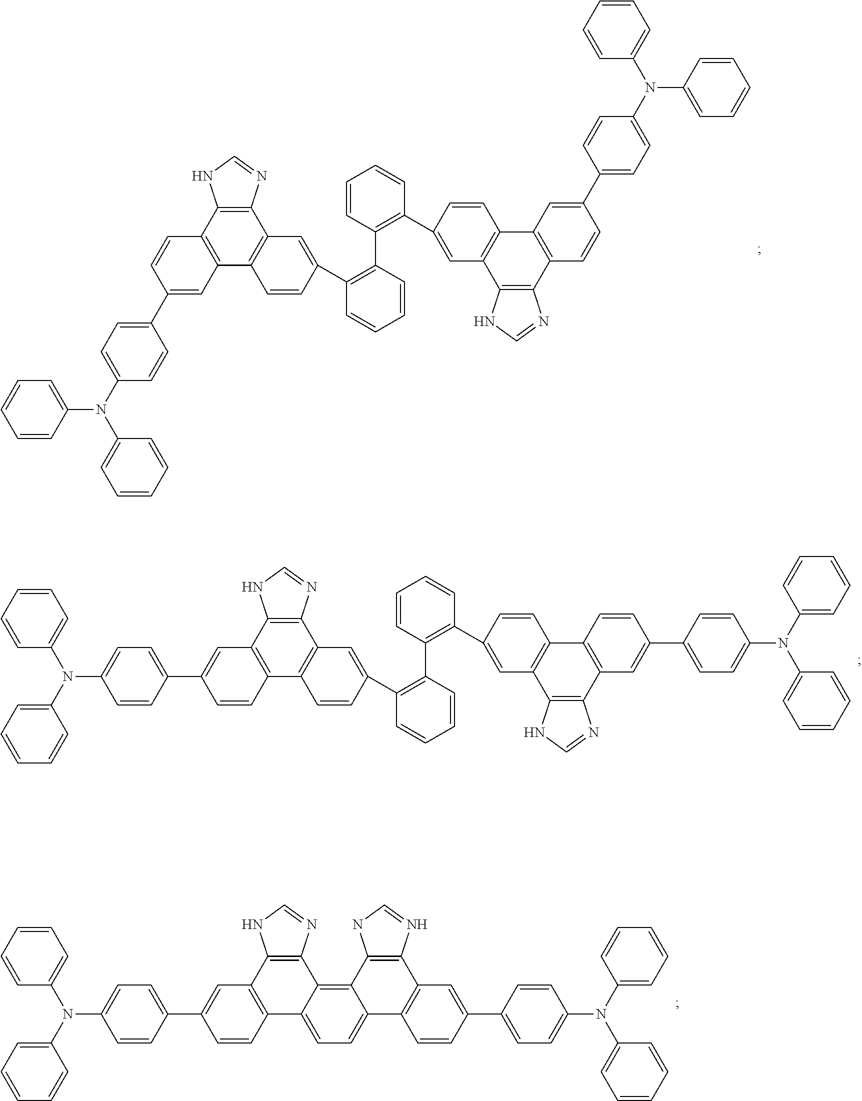 [SMILES: c1ccc(N(c2ccccc2)c2ccc(-c3ccc4c(c3)c3ccc(-c5ccccc5-c5ccccc5-c5ccc6c7cc(-c8ccc(N(c9ccccc9)c9ccccc9)cc8)ccc7c7[nH]cnc7c6c5)cc3c3[nH]cnc43)cc2)cc1 ; c1ccc(N(c2ccccc2)c2ccc(-c3ccc4c5ccc(-c6ccccc6-c6ccccc6-c6ccc7c8ccc(-c9ccc(N(c%10ccccc%10)c%10ccccc%10)cc9)cc8c8[nH]cnc8c7c6)cc5c5[nH]cnc5c4c3)cc2)cc1 ; c1ccc(N(c2ccccc2)c2ccc(-c3ccc4c(c3)c3nc[nH]c3c3c4ccc4c5ccc(-c6ccc(N(c7ccccc7)c7ccccc7)cc6)cc5c5[nH]cnc5c43)cc2)cc1]

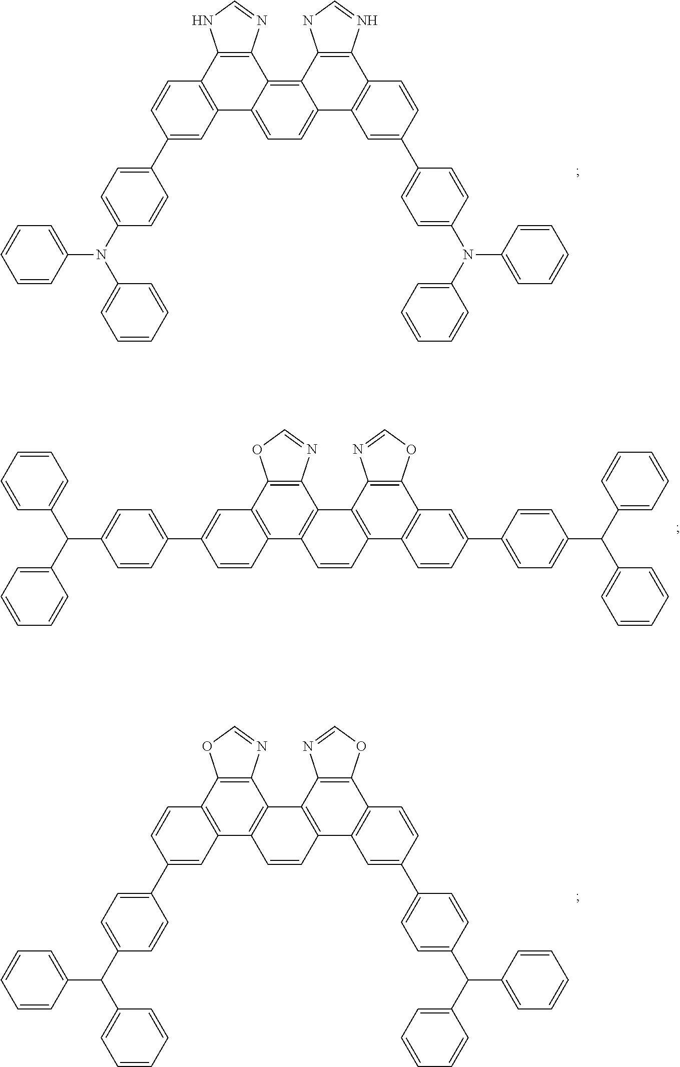 [SMILES: c1ccc(N(c2ccccc2)c2ccc(-c3ccc4c(c3)c3ccc5c6cc(-c7ccc(N(c8ccccc8)c8ccccc8)cc7)ccc6c6nc[nH]c6c5c3c3nc[nH]c43)cc2)cc1 ; c1ccc(C(c2ccccc2)c2ccc(-c3ccc4c(c3)c3ocnc3c3c4ccc4c5ccc(-c6ccc(C(c7ccccc7)c7ccccc7)cc6)cc5c5ocnc5c43)cc2)cc1 ; c1ccc(C(c2ccccc2)c2ccc(-c3ccc4c(c3)c3ccc5c6cc(-c7ccc(C(c8ccccc8)c8ccccc8)cc7)ccc6c6ocnc6c5c3c3ncoc43)cc2)cc1]

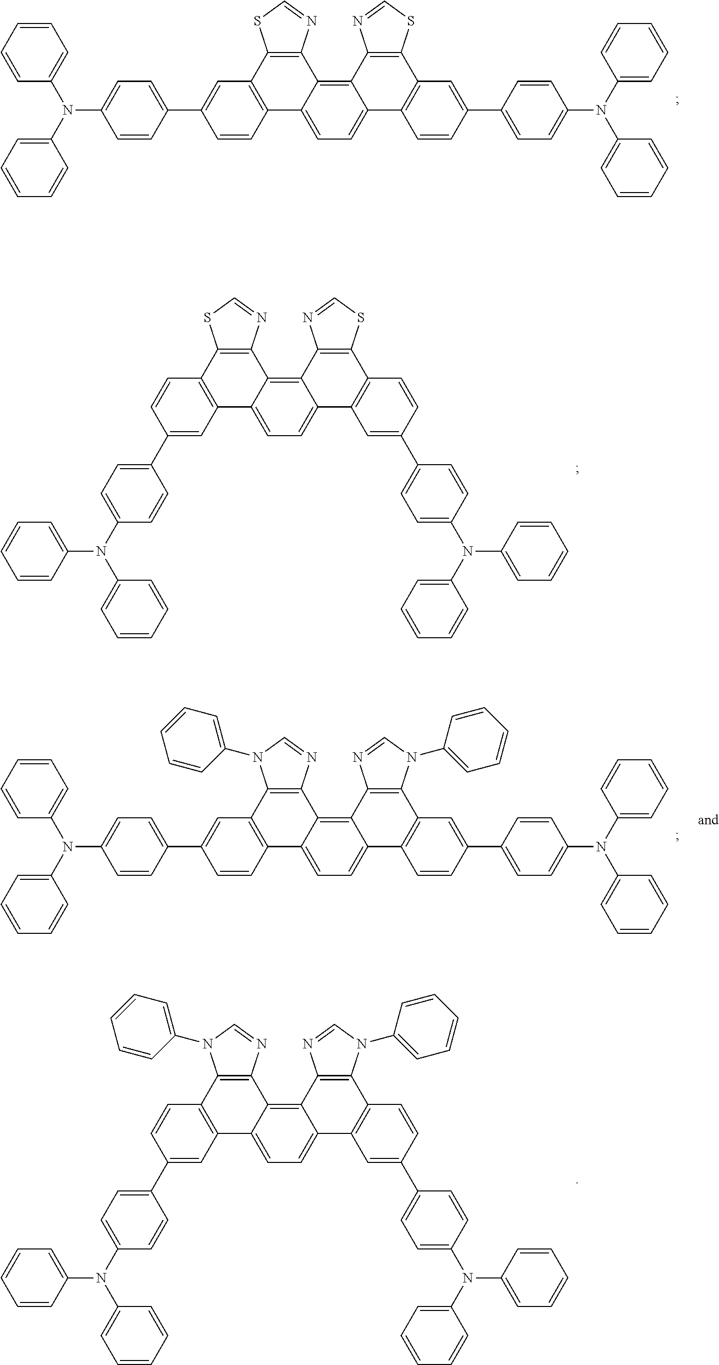 [SMILES: c1ccc(N(c2ccccc2)c2ccc(-c3ccc4c(c3)c3scnc3c3c4ccc4c5ccc(-c6ccc(N(c7ccccc7)c7ccccc7)cc6)cc5c5scnc5c43)cc2)cc1 ; c1ccc(N(c2ccccc2)c2ccc(-c3ccc4c(c3)c3ccc5c6cc(-c7ccc(N(c8ccccc8)c8ccccc8)cc7)ccc6c6scnc6c5c3c3ncsc43)cc2)cc1 ; c1ccc(N(c2ccccc2)c2ccc(-c3ccc4c5ccc6c7ccc(-c8ccc(N(c9ccccc9)c9ccccc9)cc8)cc7c7c(ncn7-c7ccccc7)c6c5c5ncn(-c6ccccc6)c5c4c3)cc2)cc1 ; c1ccc(N(c2ccccc2)c2ccc(-c3ccc4c(c3)c3ccc5c6cc(-c7ccc(N(c8ccccc8)c8ccccc8)cc7)ccc6c6c(ncn6-c6ccccc6)c5c3c3ncn(-c5ccccc5)c43)cc2)cc1]

In another aspect, the present disclosure provides a light-emitting diode comprising an anode, an emissive material layer, and a cathode on a side of the emissive material layer away from the anode; wherein the emissive material layer comprising the emissive material described herein.

Optionally, the light-emitting diode comprises a hole injection layer comprising 1,4,5,8,9,11-hexaazatriphenylene hexacarbonitrile; a hole transport layer comprising N,N′-diphenyl-N,N′-(1-naphthyl)-1,1′-biphenyl-4,4′-diamine; an electron barrier layer comprising 9,9′-diphenyl-9H,9′H-3,3′-bicarbazole; an emissive material layer comprising 9-(3-(9H-carbazol-9-yl)phenyl)-9H-3,9′-bicarbazole doped with the emissive material described herein; a hole barrier layer comprising 4,6-bis(3-(9H carbazol-9-yl)phenyl)pyrimidine; an electron transport layer comprising 9,10-bis(6-phenylpyridin-3-yl)anthracene; and an electron injection layer includes lithium fluoride; wherein the anode comprises indium tin oxide; and the cathode comprises aluminum.

Optionally, the light-emitting diode comprises a hole injection layer comprising 1,4,5,8,9,11-hexaazatriphenylene hexacarbonitrile; a hole transport layer comprising 4,4′-cyclohexene [N,N-bis(4-methylphenyl)benzenamine]; an electron barrier layer comprising 1,3-di(9H-carbazol-9-yl)benzene; an emissive material layer comprising 3,3′-Di(9H-carbazol-9-yl)-1,1′-biphenyl doped with the emissive material described herein; an electron transport layer comprising 1,3,5-Tris(3-pyridyl-3-phenyl)benzene; and an electron injection layer includes lithium fluoride; wherein the anode comprises indium tin oxide; and the cathode comprises aluminum.

In another aspect, the present disclosure provides a display apparatus, comprising the light-emitting diode described herein, and a pixel driving circuit configured to drive light emission of the light-emitting diode.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of an emissive material in some embodiments according to the present disclosure.

FIG. 2 is a schematic diagram illustrating the structure of a light-emitting diode in some embodiments according to the present disclosure.

FIG. 3 is a schematic diagram illustrating the structure of a light-emitting diode in some embodiments according to the present disclosure.

FIG. 4 is a schematic diagram illustrating the structure of a tandem light-emitting diode in some embodiments according to the present disclosure.

FIG. 5 is a schematic diagram illustrating the structure of a tandem light-emitting diode in some embodiments according to the present disclosure.

FIG. 6 is a schematic diagram illustrating the structure of a tandem light-emitting diode in some embodiments according to the present disclosure.

FIG. 7 is a schematic diagram illustrating the structure of a tandem light-emitting diode in some embodiments according to the present disclosure.

FIG. 8 is a schematic diagram illustrating the structure of a tandem light-emitting diode in some embodiments according to the present disclosure.

FIG. 9 is a schematic diagram illustrating the structure of a display substrate in some embodiments according to the present disclosure.

FIG. 10 is a circuit diagram illustrating the structure of a pixel driving circuit in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

Thermally activated delayed fluorescence materials have become promising third-generation light-emitting materials in the field of organic light-emitting diodes (OLEDs) due to their high exciton utilization efficiency, low cost, and environmental friendliness. In general, TADF materials adopt a donor-acceptor (D-A) type molecular design, which can effectively separate the highest occupied molecular orbital (HOMO) and the lowest unoccupied molecular orbital (LUMO), and has a small singlet-triplet energy gap (ΔE_{ST}), which facilitates the formation of singlet exciton by triplet exciton reverse intersystem crossing (RISC), thus realizing color-tunable and efficient OLEDs.

The inventors of the present disclosure discover that there are very few high-efficiency red TADF materials available. The inventors of the present disclosure discover that this is due to several reasons. According to the energy gap law, the non-radiative rate constant (kₙᵣ) of the lowest singlet state (Si) increases exponentially with increasing wavelength of luminescence, which leads to a lower photoluminescence quantum yield (PLQY) of the material in the red light wavelength range. The stronger donor or acceptor in red TADF materials sufficiently separates HOMO and LUMO, which usually leads to a decrease in the oscillator intensity and radiative rate constant (kᵣ) of the singlet state. The influence of molecular structure (rigidity, planarity, conjugated degree, etc.) on efficient red emission is difficult to be fully considered during molecular design. The inventors of the present disclosure discover that the development of high-efficiency red-emitting TADF materials should focus on suppression of nonradiative deactivation of the exciton.

The inventors of the present disclosure consider several factors in designing the novel TADF materials according to the present disclosure, including twisted D-A structures, spatial D-A interactions such as exciplex type, multiple resonance structures, selection of specific D and A chromophores and their dihedral angles, and introduction of additional donors to form D-A-D or D-A-D′ structures. The inventors of the present disclosure discover a novel class of TADF materials that have appropriate spatial interactions, high horizontal dipole ratio, and low nonradiative decay rate, achieving highly efficient light emission.

Accordingly, the present disclosure provides, inter alia, an emissive material, a light-emitting diode, and a display apparatus that substantially obviate one or more of the problems due to limitations and disadvantages of the related art. In one aspect, the present disclosure provides an emissive material. In some embodiments, the emissive material has a molecular structure formula of (D)m-(A)q-(D)m′, wherein D stands for a donor moiety of a molecule of the emissive material configured as an electron donating part of the molecule upon excitation, D being a part of the molecule where at least one occupied orbital of the molecule is distributed (e.g., where highest occupied orbitals of the molecule are distributed); A stands for an acceptor moiety of the molecule of the emissive material configured as an electron accepting part of the molecule upon excitation, A being a part of the molecule where at least one unoccupied orbital of the molecule is distributed (e.g., wherein lowest unoccupied orbitals of the molecule are distributed); m and m′ are positive integers greater than 0; and q is a positive integer greater than 1. The emissive material according to the present disclosure achieves a high horizontal dipole ratio (Θ_{∥}) due to the fact that horizontal molecular orientation (EDO) is parallel to molecular orientation and along long axis of the molecule. Moreover, the emissive material according to the present disclosure distributes the frontier molecular orbital all across the molecular to minimize the ΔE_{ST} for obtaining an excellent electronic properties and improved PLQY.

In some embodiments, the emissive material is a thermally activated delayed fluorescence material having two donor moieties and two acceptor moieties in one single molecule. As used herein, the term “donor moiety” refers to a moiety of a molecule of the emissive material configured as an electron donating part of the molecule upon excitation, the donor moiety being a part of the molecule where at least one occupied orbital of the molecule is distributed (e.g., where highest occupied orbitals of the molecule are distributed). Occupied orbitals of the molecule are mainly distributed in the donor moiety. As used herein, the term “acceptor moiety” refers to a moiety of the molecule of the emissive material configured as an electron accepting part of the molecule upon excitation, the acceptor moiety being a part of the molecule where at least one unoccupied orbital of the molecule is distributed (e.g., wherein lowest unoccupied orbitals of the molecule are distributed). Unoccupied orbitals of the molecule are mainly distributed in the acceptor moiety.

In some embodiments, the emissive material has a molecular structure formula of (D)m-(A)q-(D)m′, wherein D stands for a donor moiety, A stands for an acceptor moiety, m, and m′ are positive integers greater than 0 (e.g., 1, 2, 3, 4, 5, 6, 7, 8, 9, or 10). Optionally, q is a positive integer greater than 1 (e.g., 2, 3, 4, 5, 6, 7, 8, 9, 10). Examples of appropriate molecular structure formulas include D1-dA-D2, D1-tA-D2, D1-qA-D2, D1-qiA-D2, D1-sA-D2, D1-spA-D2, D1-oA-D2, wherein D1 stands for a first donor moiety, D2 stands for a second donor moiety, dA comprises two acceptor moieties, tA comprises three acceptor moieties, qA comprises four acceptor moieties, qiA comprises five acceptor moieties, sA comprises six acceptor moieties, spA comprises seven acceptor moieties, oA comprises eight acceptor moieties. Examples of appropriate molecular structure formulas further include dD1-(A)n-dD2, tD1-(A)n-tD2, qD1-(A)n-qD2, wherein n is a positive integer greater than 0, A stands for an acceptor moiety, dD1 comprises two donor moieties, dD2 comprises two donor moieties, tD1 comprises three donor moieties, tD2 comprises three donor moieties, qD1 comprises four donor moieties, and qD2 comprises four donor moieties.

In some embodiments, the emissive material has a molecular structure formula of D1-dA-D2, wherein D1 stands for a first donor moiety, D2 stands for a second donor moiety, and dA comprises a first acceptor moiety and a second acceptor moiety. In some embodiments, the first acceptor moiety and the second acceptor moiety are covalently linked to each other. In one example, the first donor moiety and the second donor moiety are the same. In another example, the first donor moiety and the second donor moiety are different from each other. In one example, the first acceptor moiety and the second acceptor moiety are the same. In another example, the first acceptor moiety and the second acceptor moiety are different from each other.

In some embodiment, dA is -L-, the emissive material has a molecular structure formula of D1-A1-L-A2-D2, wherein D1 stands for a first donor moiety; D2 stands for a second donor moiety; A1 stands for a first acceptor moiety; A2 stands for a second acceptor moiety; L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, or substituted or unsubstituted heteroarylene, and n is an integer equal to or greater than 0. Optionally, n is 0, 1 or 2.

In some embodiments, L is bond. Optionally, L is a single bond.

In some embodiments, L is a substituted or unsubstituted arylene. In one particular example, L is selected from the group consisting of

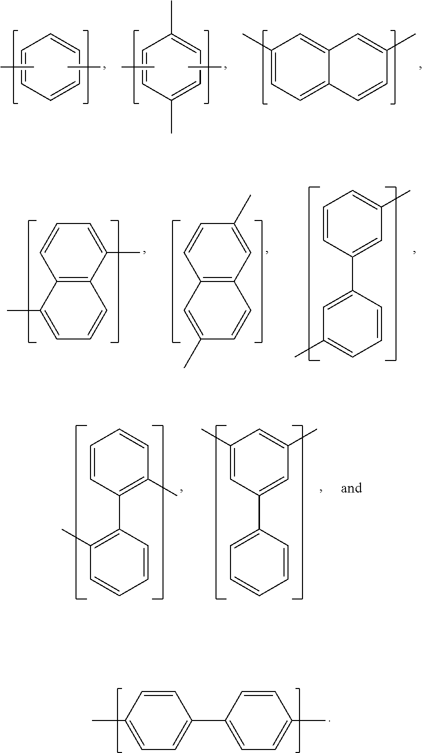

In some embodiment, dA is -[A1′-cfg-A2′]-, and the emissive material has a molecular structure formula of D1-[A1′-cfg-A2′]-D2, wherein D1 stands for the first donor moiety, D2 stands for the second donor moiety, A1′-cfg stands for the first acceptor moiety A1, cfg-A2′ stands for the second acceptor moiety A2, the first acceptor moiety A1 and the second acceptor moiety A2 share a common functional group cfg. Optionally, the common functional group cfg is a functional group comprising a conjugated diene or a conjugated polyene.

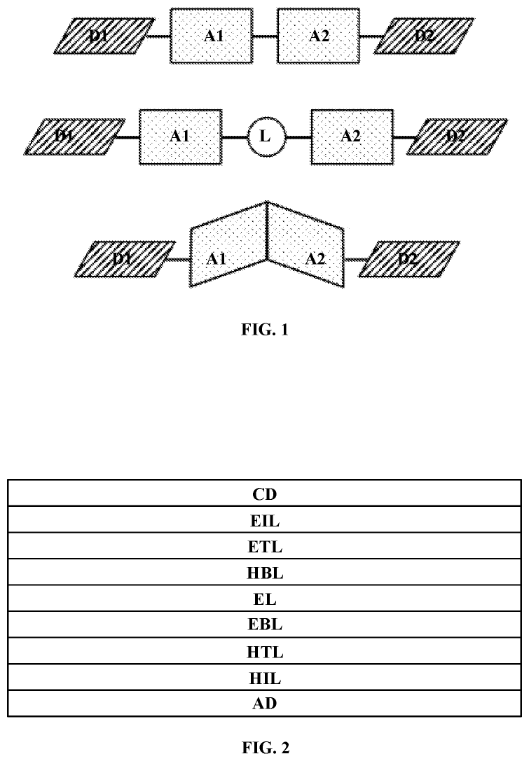

FIG. 1 is a schematic diagram illustrating the structure of an emissive material in some embodiments according to the present disclosure. Referring to FIG. 1, the top structure illustrates the structure of an emissive material having a molecular structure formula of D1-A1-A2-D2 and L is a single bond; the structure in the middle illustrates the structure of an emissive material having a molecular structure formula of D1-A1-L-A2-D2 and L is a substituted or unsubstituted arylene; the bottom structure illustrates the structure of an emissive material having a molecular structure formula of D1-[A1′-cfg-A2′]-D2, wherein A1′-cfg represents A1, and cfg-A2′ represents A2. As shown in FIG. 1, in all three classes of molecular structures, any donor-acceptor pair having a donor and an acceptor directly connected to each other (e.g., D1-A1 or D2-A2) has a non-zero (e.g., greater than 20 degrees, greater than 30 degrees, greater than 40 degrees, greater than 50 degrees, greater than 60 degrees, greater than 70 degrees, or greater than 80 degrees) dihedral angle (e.g., a twisted angle) between a plane of the donor moiety and a plane of the acceptor moiety. This particular feature increases the volume of the molecule, leading to a decreased molecular aggregation during formation of an emissive material layer using the emissive material. The present emissive material has a reduced triplet-triplet annihilation (TTA) and singlet-polaron annihilation (SPA). Moreover, the first acceptor moiety A1 and the second acceptor moiety A2 are substantially co-planar, allowing electron interactions between the first acceptor moiety A1 and the second acceptor moiety A2 to modulate excited state energy levels and promote radiative decay of excited state.

In some embodiments, the first acceptor moiety A1 or the second acceptor moiety A2 is a phenanthro-azole moiety. Examples of phenanthro-azole moieties include a phenanthro-imidazole moiety, a phenanthro-thiazole moiety, and a phenanthro-oxazole moiety. The inventors of the present disclosure discover that the phenanthro-azole moieties have a high luminescence efficiency, suitable forbidden band width, excellent thermal stability and carrier transport ability. The phenanthro-azole moieties having these unique properties exhibit fast radiation decay rates and high PLQY, while promoting device carrier balance and high external quantum efficiency (EQE).

In some embodiments, the emissive material has a molecular structure formula of:

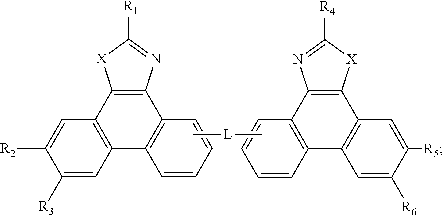

wherein X is —NH—, —O—, —S—, or N—R₀; R₀, R₁, R₄ are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures); L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, or substituted or unsubstituted heteroarylene, or —P(O)(NL³R²)N—; at least one of R₂ and R₃ is a donor moiety; and at least one of R₅ and R₆ is a donor moiety. Optionally, one of R₂ and R₃ is a donor moiety, and the other one of R₂ and R₃ is hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures). Optionally, one of R₅ and R₆ is a donor moiety, and the other one of R₅ and R₆ is hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures).

Optionally, R₁ and R₄ are independently hydrogen.

Various appropriate donor moieties may be used in the present emissive material. In some embodiments, at least one of R₂ and R₃ is an aromatic amine group, e.g., an aromatic tertiary amine group. In some embodiments, at least one of R₅ and R₆ is an aromatic amine group, e.g., an aromatic tertiary amine group. Examples of aromatic amine groups include a diphenylamine group, a carbazole group, an acridine group, and a phenoxazine group. Specific examples of aromatic amine groups include.

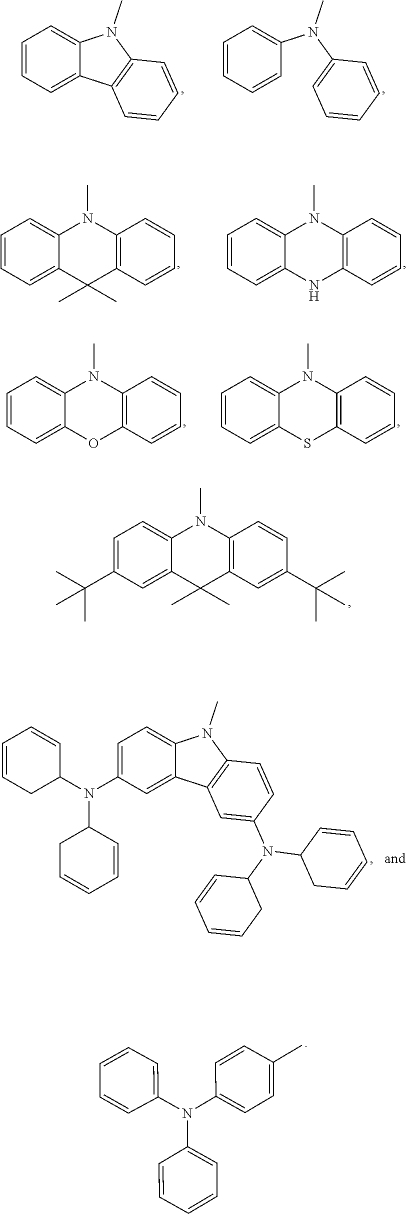

In some embodiments, L is a single bond. Optionally, the emissive material has a molecular structure formula of.

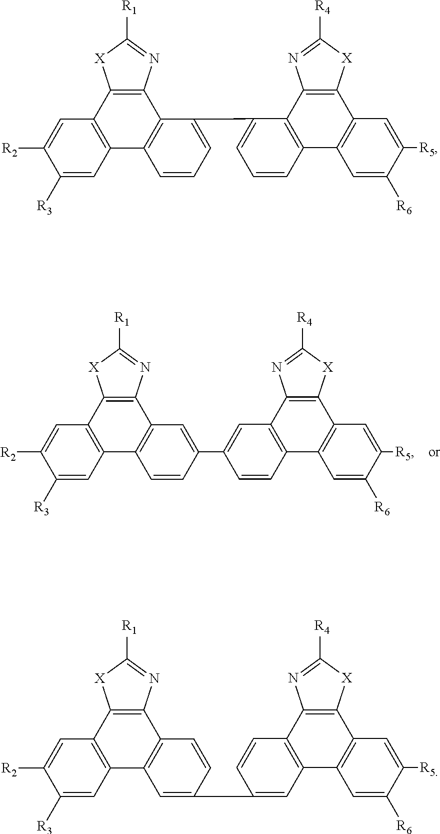

Specific examples of the emissive materials include:

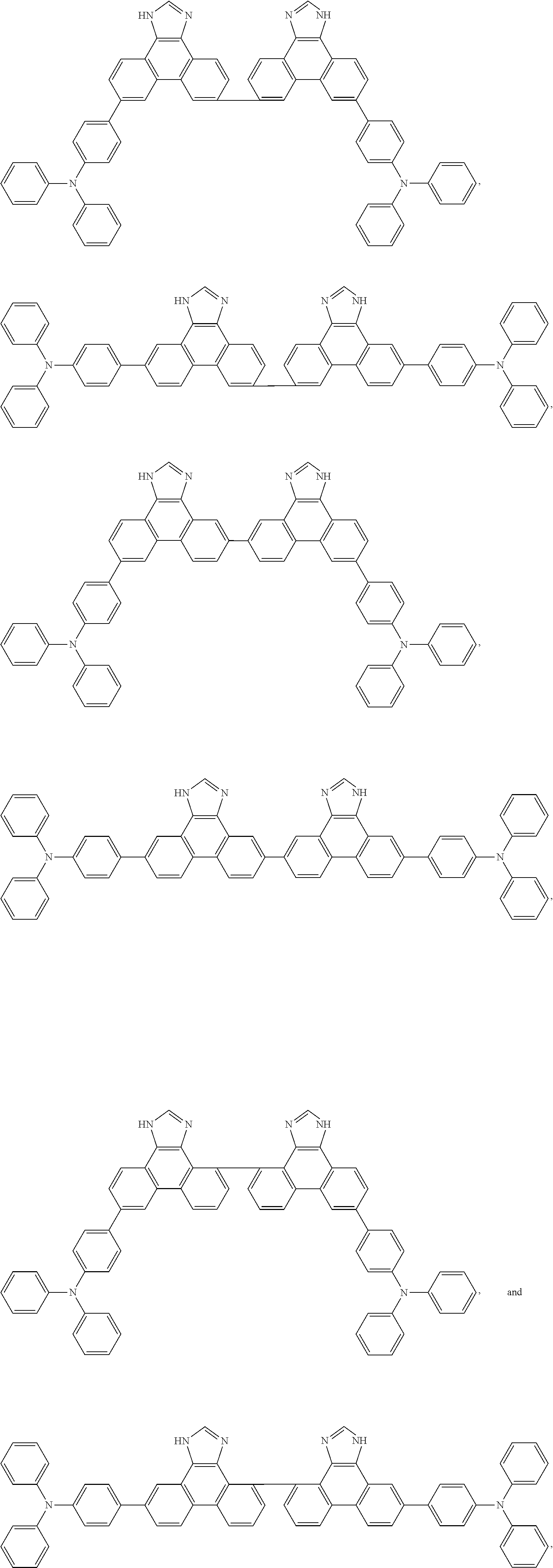

In some embodiments, L is phenyl biphenyl or naphthyl. Optionally, L is selected from the group consisting of

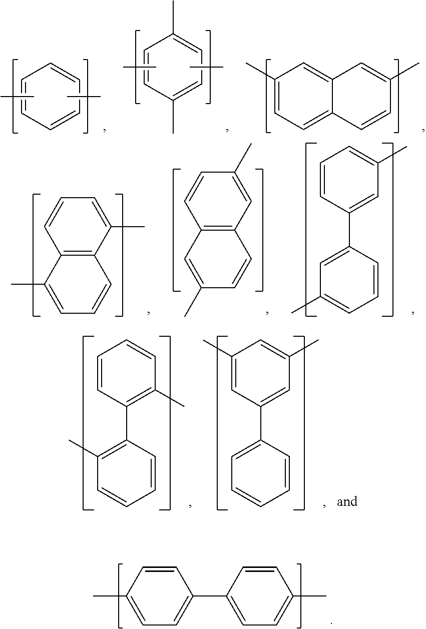

Specific examples of the emissive materials include.

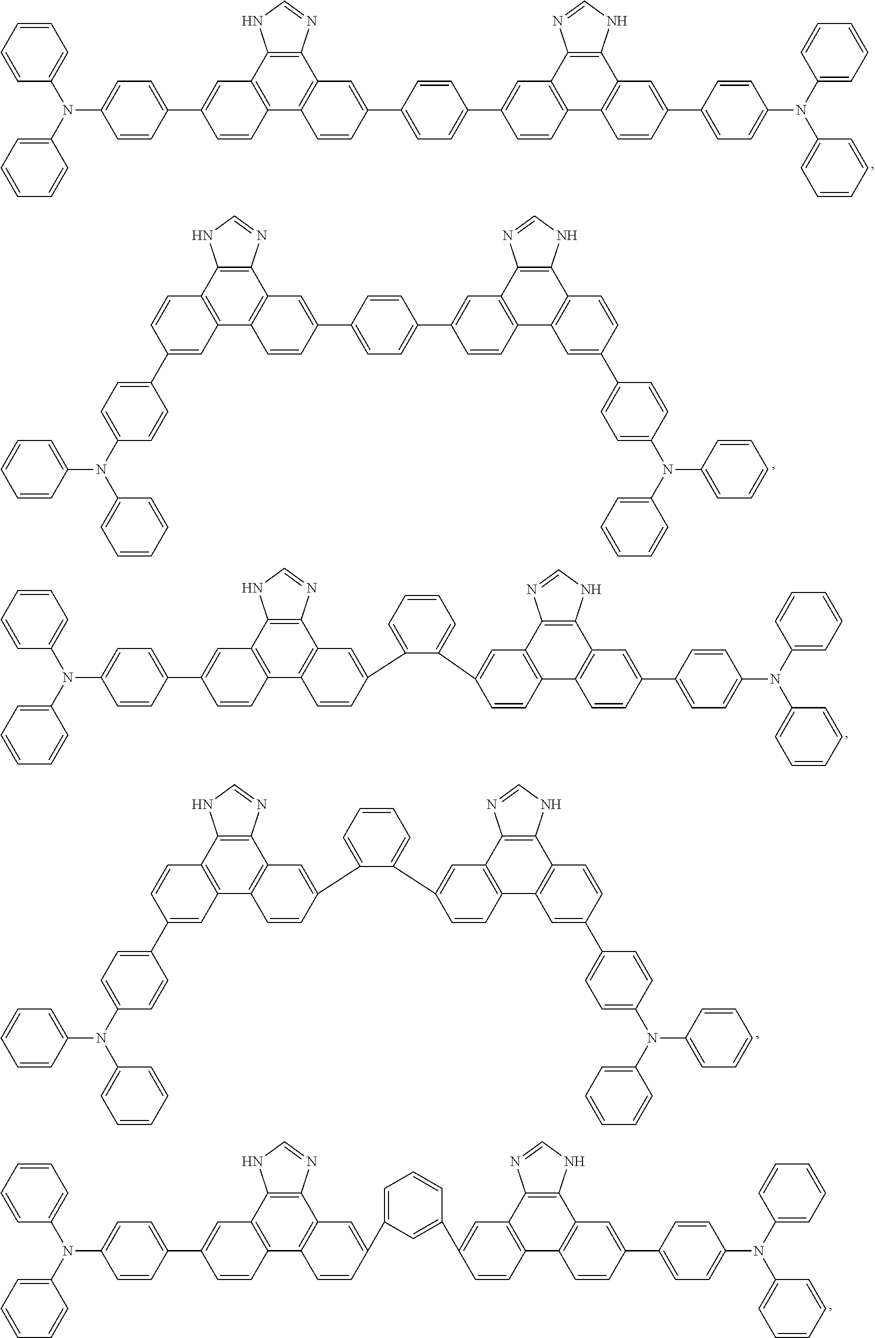

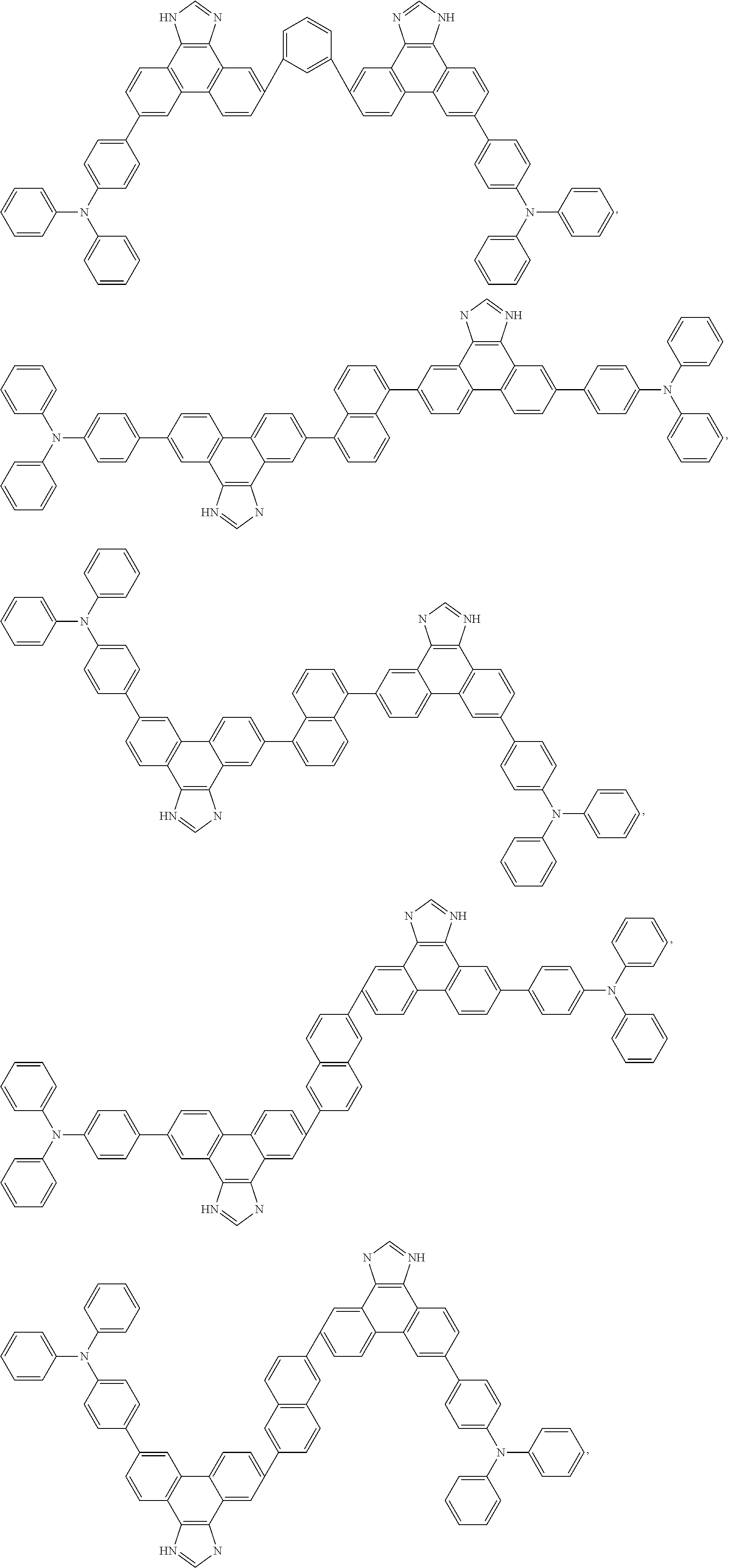

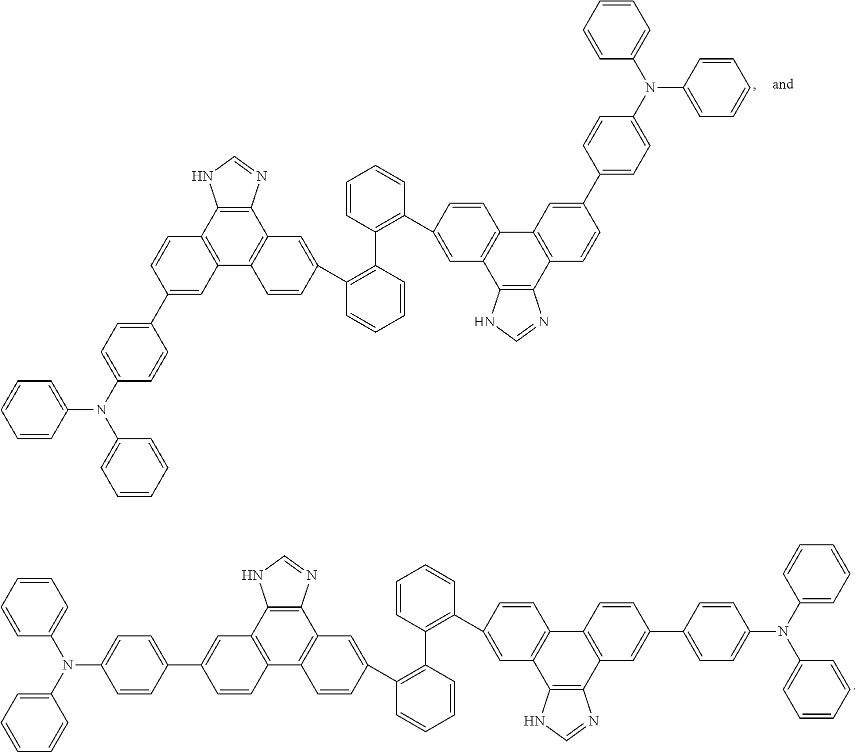 [SMILES: c1ccc(N(c2ccccc2)c2ccc(-c3ccc4c(c3)c3ccc(-c5ccccc5-c5ccccc5-c5ccc6c7cc(-c8ccc(N(c9ccccc9)c9ccccc9)cc8)ccc7c7[nH]cnc7c6c5)cc3c3[nH]cnc43)cc2)cc1 ; c1ccc(N(c2ccccc2)c2ccc(-c3ccc4c5ccc(-c6ccccc6-c6ccccc6-c6ccc7c8ccc(-c9ccc(N(c%10ccccc%10)c%10ccccc%10)cc9)cc8c8[nH]cnc8c7c6)cc5c5[nH]cnc5c4c3)cc2)cc1]

In some embodiments, the emissive material has a molecular structure formula of:

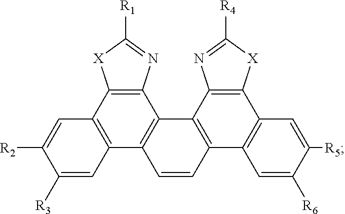

wherein X is —NH—, —O—, —S—, or N—R₀; R₀, R₁, R₄ are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures); at least one of R₂ and R₃ is a donor moiety; and at least one of R₅ and R₆ is a donor moiety. Optionally, one of R₂ and R₃ is a donor moiety, and the other one of R₂ and R₃ is hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures). Optionally, one of R₅ and R₆ is a donor moiety, and the other one of R₅ and R₆ is hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures).

Optionally, R₁ and R₄ are independently hydrogen.

Various appropriate donor moieties may be used in the present emissive material. In some embodiments, at least one of R₂ and R₃ is an aromatic amine group, e.g., an aromatic tertiary amine group. In some embodiments, at least one of R₅ and R₆ is an aromatic amine group, e.g., an aromatic tertiary amine group. Examples of aromatic amine groups include a diphenylamine group, a carbazole group, an acridine group, and a phenoxazine group. Specific examples of aromatic amine groups include:

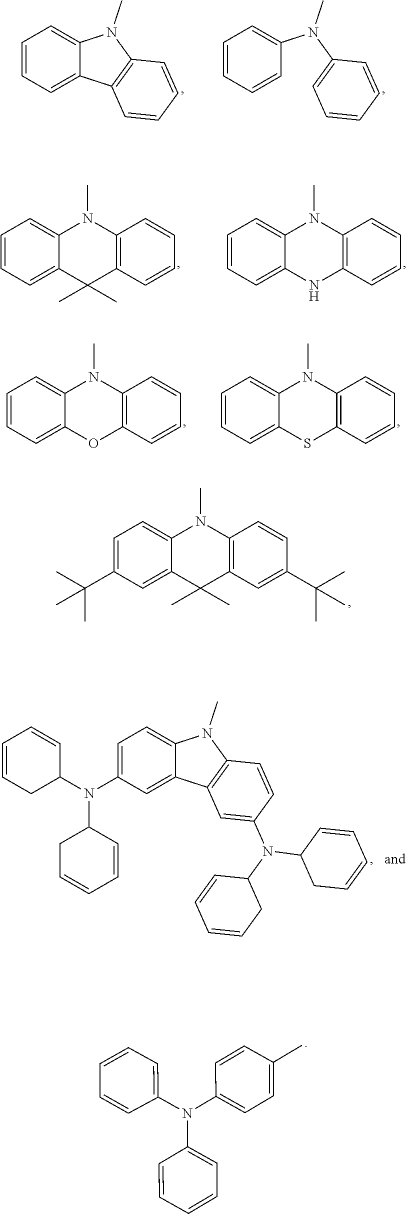

Specific examples of the emissive materials include.

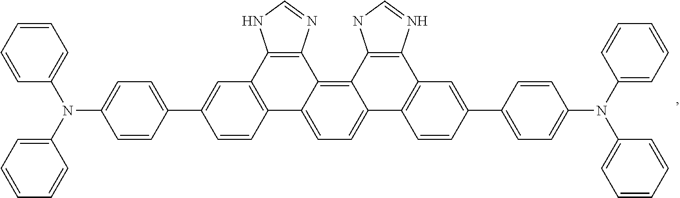 [SMILES: c1ccc(N(c2ccccc2)c2ccc(-c3ccc4c(c3)c3nc[nH]c3c3c4ccc4c5ccc(-c6ccc(N(c7ccccc7)c7ccccc7)cc6)cc5c5[nH]cnc5c43)cc2)cc1]

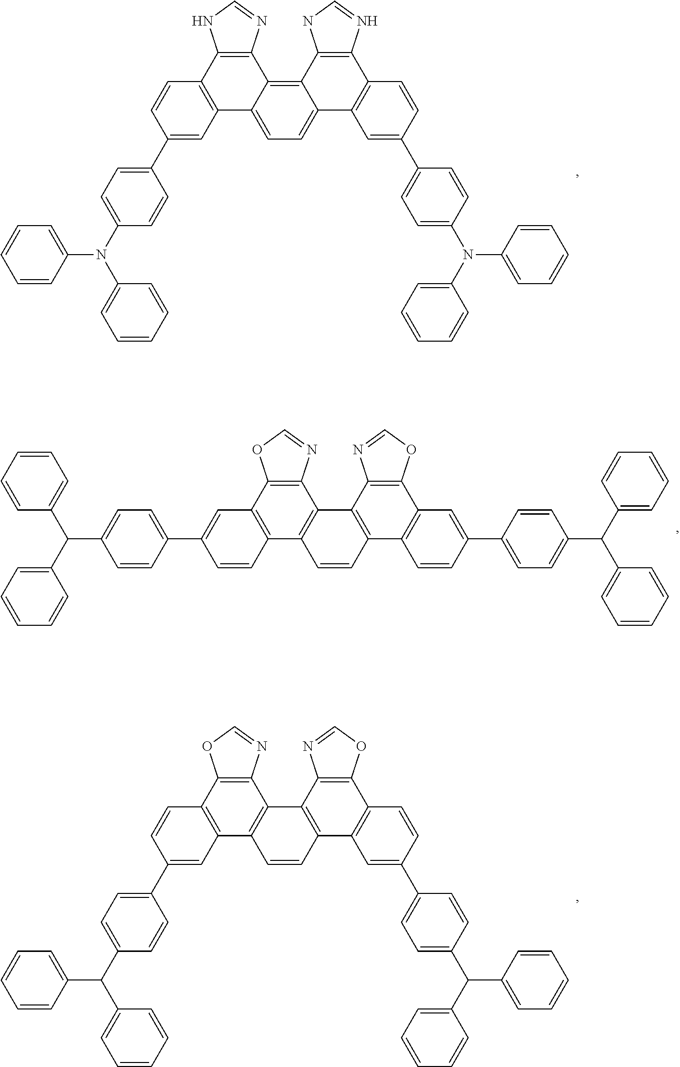 [SMILES: c1ccc(N(c2ccccc2)c2ccc(-c3ccc4c(c3)c3ccc5c6cc(-c7ccc(N(c8ccccc8)c8ccccc8)cc7)ccc6c6nc[nH]c6c5c3c3nc[nH]c43)cc2)cc1 ; c1ccc(C(c2ccccc2)c2ccc(-c3ccc4c(c3)c3ocnc3c3c4ccc4c5ccc(-c6ccc(C(c7ccccc7)c7ccccc7)cc6)cc5c5ocnc5c43)cc2)cc1 ; c1ccc(C(c2ccccc2)c2ccc(-c3ccc4c(c3)c3ccc5c6cc(-c7ccc(C(c8ccccc8)c8ccccc8)cc7)ccc6c6ocnc6c5c3c3ncoc43)cc2)cc1]

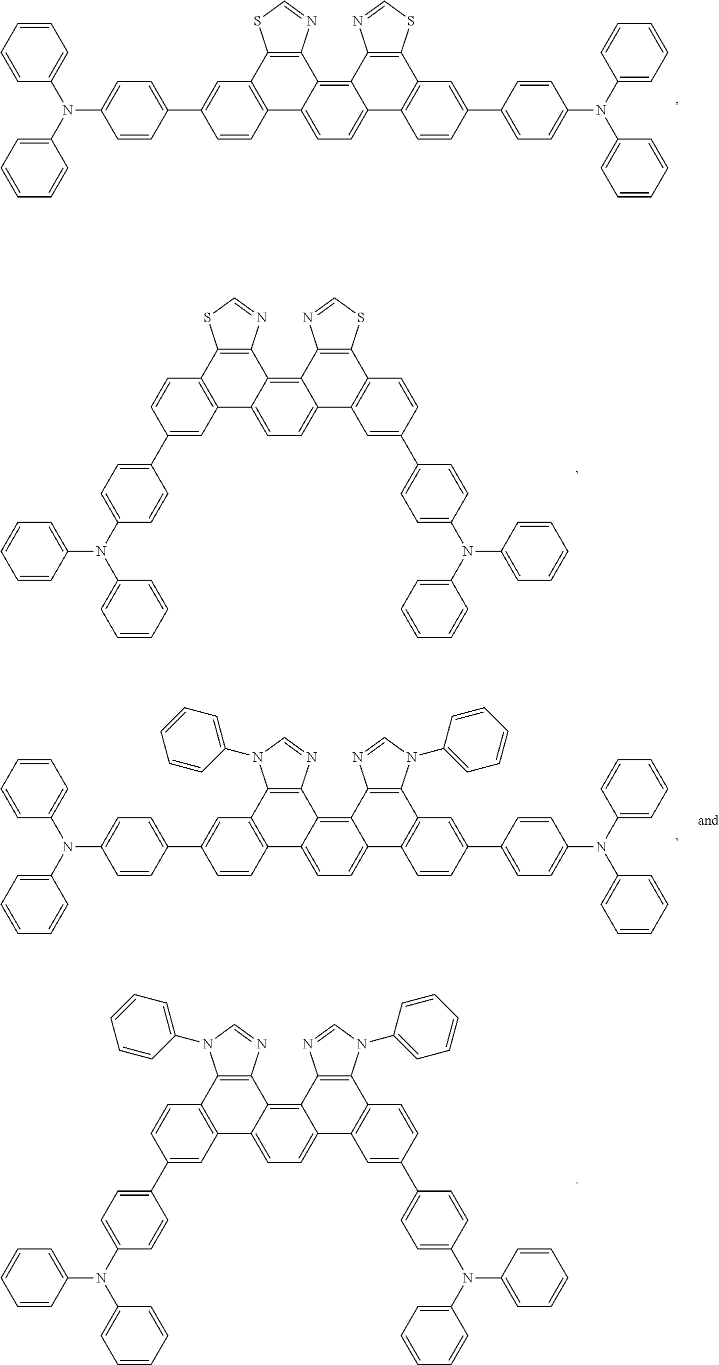 [SMILES: c1ccc(N(c2ccccc2)c2ccc(-c3ccc4c(c3)c3scnc3c3c4ccc4c5ccc(-c6ccc(N(c7ccccc7)c7ccccc7)cc6)cc5c5scnc5c43)cc2)cc1 ; c1ccc(N(c2ccccc2)c2ccc(-c3ccc4c(c3)c3ccc5c6cc(-c7ccc(N(c8ccccc8)c8ccccc8)cc7)ccc6c6scnc6c5c3c3ncsc43)cc2)cc1 ; c1ccc(N(c2ccccc2)c2ccc(-c3ccc4c5ccc6c7ccc(-c8ccc(N(c9ccccc9)c9ccccc9)cc8)cc7c7c(ncn7-c7ccccc7)c6c5c5ncn(-c6ccccc6)c5c4c3)cc2)cc1 ; c1ccc(N(c2ccccc2)c2ccc(-c3ccc4c(c3)c3ccc5c6cc(-c7ccc(N(c8ccccc8)c8ccccc8)cc7)ccc6c6c(ncn6-c6ccccc6)c5c3c3ncn(-c5ccccc5)c43)cc2)cc1]

Various appropriate methods may be used for synthesizing the emissive materials according to the present disclosure.

In one example, 1 mol of dibenzimidazole derivatives and iodine are dispersed in benzene solution to conduct a photochemical reaction under UV light. A phenanthroimidazole derivative is obtained as a result of the reaction, as illustrated below:

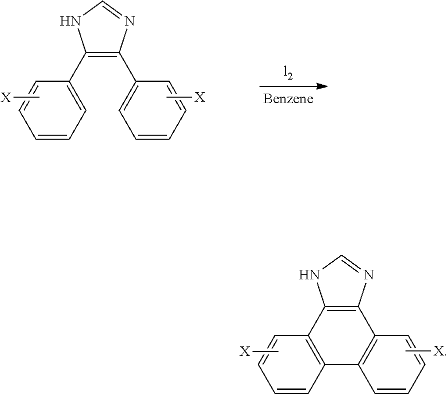

Under N₂ atmosphere, 2˜3.5 mol of phenanthroimidazole derivatives, 1 mol of aromatic boronic acids, 0.05 mol of Pd(PPh₃)₄ catalyst, and 0.05 mol of K₂CO₃ were placed in a mixture of toluene, ethanol and water. The reaction mixture was heated in a reflux apparatus. The reaction product was extracted, and purified by column chromatography to obtain an intermediate. This step of the reaction is illustrated below:

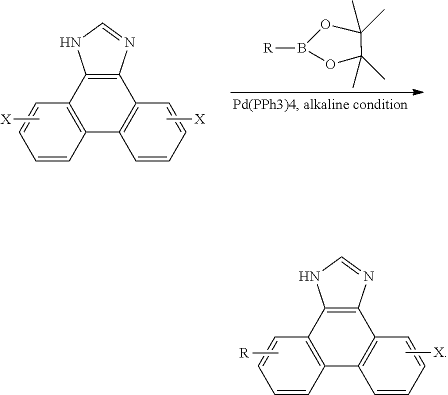

Under N₂ atmosphere, 1 mol of the intermediate, 2˜3.5 mol of pinacol ester, 0.05 mol Pd(PPh₃)₄ catalyst, and 0.05 mol K₂CO₃ were dispersed in a mixture of toluene, ethanol and water. The reaction mixture was heated in a reflux apparatus. The reaction product was extracted, and purified by column chromatography to obtain the target product, as illustrated below:

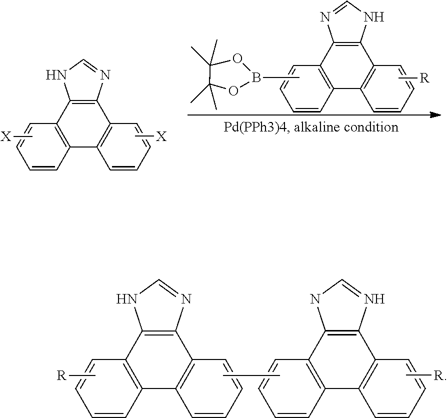

In another example, under N₂ atmosphere, 2 mol of phenanthroimidazole derivatives, 1 mol of 1,4-benzenediboronic acid, 0.1 mol of Pd(PPh₃)₄ catalyst, and 0.1 mol of K₂CO₃ were dispersed in a mixture of toluene, ethanol and water. The reaction mixture was heated in a reflux apparatus. The reaction product was extracted, and purified by column chromatography to obtain the target product, as illustrated below:

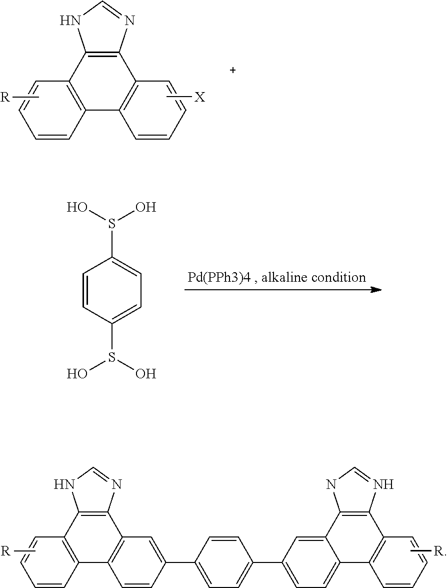

In another example, under N₂ atmosphere, 2.75 mol boronic ester, 1.20 mol 2,3-dichloro-1,4-diiodobenzene, 5.00 mol LiOH·H₂O were added to THF and H₂O, followed by adding 0.063 mol Pd₂dba₃ (0.057 g), and 0.25 mol SPhos. The mixture was reacted at 50° C. for 3 hours. After cooling, the reaction mixture was diluted with ethyl acetate, treated with NH₄Cl, and washed with water (20 mL) and brine (10 mL). The intermediate was obtained by extraction and dried. The intermediate was dissolved in acetone and aqueous Na₂CO₃ solution was added, and the target product was obtained by filtration after 300 nm UV irradiation for 46 h. The reaction is illustrated below:

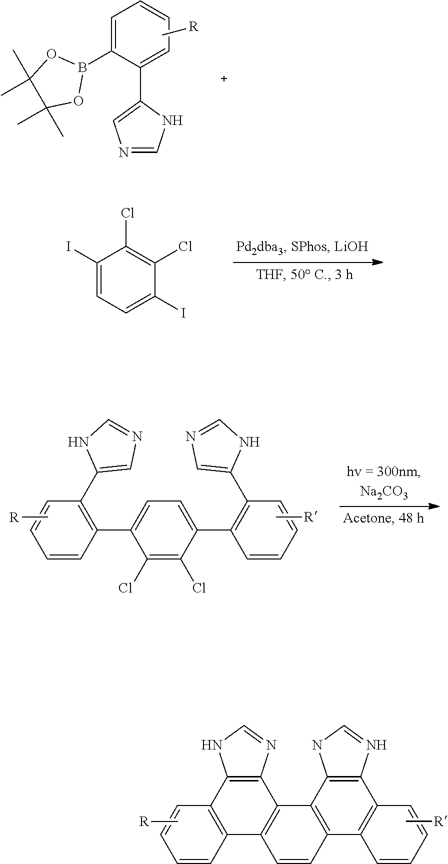

Several exemplary reaction products were analyzed. In one example, the reaction product is:

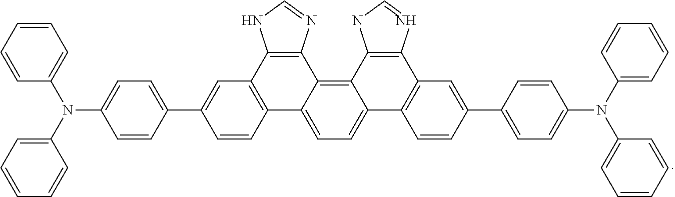 [SMILES: c1ccc(N(c2ccccc2)c2ccc(-c3ccc4c(c3)c3nc[nH]c3c3c4ccc4c5ccc(-c6ccc(N(c7ccccc7)c7ccccc7)cc6)cc5c5[nH]cnc5c43)cc2)cc1]

The reaction product has a molecular formula of C₅₄H₃₆N₆; and a molecular weight of 768.92; a theoretical element composition of C, 84.35; H, 4.72; N, 10.93; an experimental element composition of C, 84.31; H, 4.74; N, 10.97. Peaks in ¹H NMR 400 MHz, DMSO-d6) include δ (ppm)=12.31(s, 2H, —NH), 9.14(d, 2H, -Ph), 8.87(d, 2H, -Ph), 8.46-8.41(m, 4H, -Ph), 8.16(s, 2H, -Im), 7.91(s, 2H, -Ph), 7.60(d, 2H, -Ph), 7.29-7.21(m, 8H, -Ph), 7.10-7.00(m, 12H, -Ph).

In another example, the reaction product is:

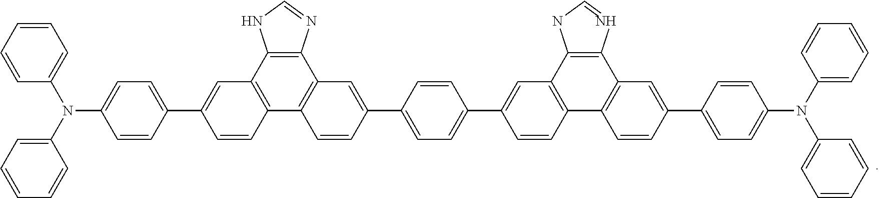 [SMILES: c1ccc(N(c2ccccc2)c2ccc(-c3ccc4c5ccc(-c6ccc(-c7ccc8c9ccc(-c%10ccc(N(c%11ccccc%11)c%11ccccc%11)cc%10)cc9c9[nH]cnc9c8c7)cc6)cc5c5[nH]cnc5c4c3)cc2)cc1]

The reaction product has a molecular formula of C₆₀H₄₀N₆; and a molecular weight of 845.02; a theoretical element composition of C, 85.28; H, 4.77; N, 9.95; an experimental element composition of C, 85.30; H, 4.74; N, 9.97. Peaks in ¹H NMR 400 MHz, DMSO-d6) include δ (ppm)=12.24(s, 2H, —NH), 9.10(d, 2H, -Ph), 8.81(d, 2H, -Ph), 8.45-8.40(m, 4H, -Ph), 8.17(s, 2H, -Im), 7.84(s, 2H, -Ph), 7.61(d, 2H, -Ph), 7.26-7.19(m, 12H, -Ph), 7.10-6.98(m, 12H, -Ph).

In another example, the reaction product is:

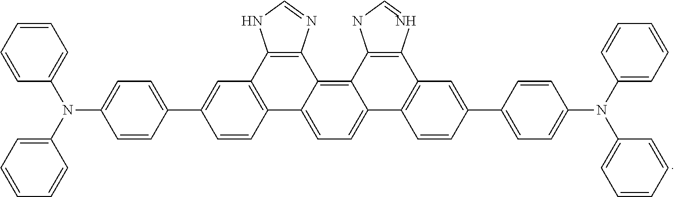 [SMILES: c1ccc(N(c2ccccc2)c2ccc(-c3ccc4c(c3)c3nc[nH]c3c3c4ccc4c5ccc(-c6ccc(N(c7ccccc7)c7ccccc7)cc6)cc5c5[nH]cnc5c43)cc2)cc1]

The reaction product has a molecular formula of C₄₈H₃₂N₆; and a molecular weight of 692.83; a theoretical element composition of C, 83.21; H, 4.66; N, 12.13; an experimental element composition of C, 83.16; H, 4.69; N, 12.18. Peaks in ¹H NMR 400 MHz, DMSO-d6) include δ (ppm)=12.17(s, 2H, —NH), 8.92(d, 2H, -Ph), 8.23(s, 2H, -Im), 7.94(s, 2H, -Ph), 7.78-7.64(m, 4H, -Ph), 7.24-7.19(m, 8H, -Ph), 7.06-6.97(m, 12H, -Ph).

In another aspect, the present disclosure provides an emissive material layer comprising the emissive material here.

In another aspect, the present disclosure provides a light-emitting diode comprising the emissive material layer described herein. In some embodiments, the light-emitting diode includes an anode, the emissive material layer described herein, and a cathode on a side of the emissive material layer away from the anode.

FIG. 2 is a schematic diagram illustrating the structure of a light-emitting diode in some embodiments according to the present disclosure. Referring to FIG. 2, the light-emitting diode in some embodiments includes an anode AD, a hole injection layer HIL on the anode AD, a hole transport layer HTL on a side of the hole injection layer HIL away from the anode AD, an electron barrier layer EBL on a side of the hole transport layer HTL away from the hole injection layer HIL, an emissive material layer EL on a side of the electron barrier layer EBL away from the hole transport layer HTL, a hole barrier layer HBL on a side of the emissive material layer EL away from the electron barrier layer EBL, an electron transport layer ETL on a side of the hole barrier layer HBL away from the emissive material layer EL, an electron injection layer EIL on a side of the electron transport layer ETL away from the hole barrier layer HBL, and a cathode CD on a side of the electron injection layer EIL away from the electron transport layer ETL.

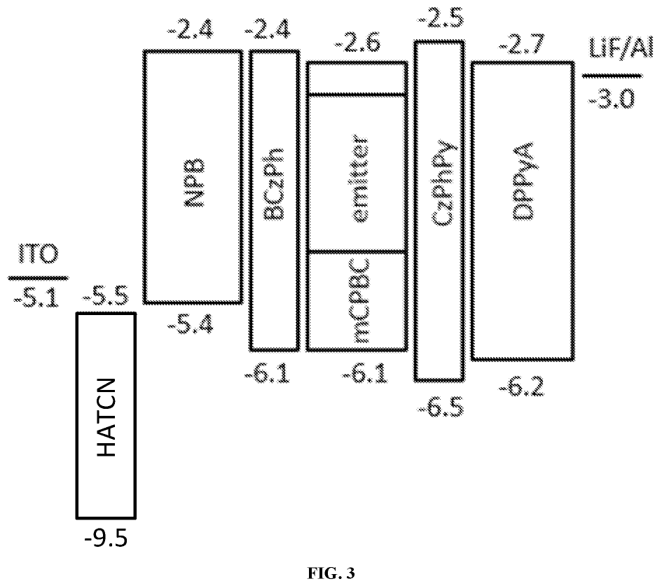

FIG. 3 is a schematic diagram illustrating the structure of a light-emitting diode in some embodiments according to the present disclosure. Referring to FIG. 3, the anode of the light-emitting diode includes indium tin oxide ITO with a lowest unoccupied molecular orbital (LUMO) energy level of −5.1 eV. The hole injection layer includes 1,4,5,8,9,11-hexaazatriphenylene hexacarbonitrile (HATCN) having a LUMO energy level of −5.5 eV and a highest occupied molecular orbital (HOMO) energy level of −9.5 ev. The hole transport layer includes N,N′-diphenyl-N,N′-(1-naphthyl)-1,1′-biphenyl-4,4′-diamine (NPB) having a LUMO energy level of −2.4 eV and a HOMO energy level of −5.4 eV. The electron barrier layer includes 9,9′-diphenyl-9H,9′H-3,3′-bicarbazole (BCzPh) having a LUMO energy level of −2.4 eV and a HOMO energy level of −6.1 eV. The emissive material layer includes 9-(3-(9H-carbazol-9-yl)phenyl)-9H-3,9′-bicarbazole (mCPBC, host) doped with an emitter (the emissive material according to the present disclosure, guest), having a LUMO energy level of −2.6 eV and a HOMO energy level of −6.1 eV. The hole barrier layer includes 4,6-bis(3-(9H carbazol-9-yl)phenyl)pyrimidine (CzPhPy) having a LUMO energy level of −2.5 eV and a HOMO energy level of −6.5 eV. The electron transport layer includes 9,10-bis(6-phenylpyridin-3-yl)anthracene (DPPyA) having a LUMO energy level of −2.7 eV and a HOMO energy level of −6.2 eV. The electron injection layer includes lithium fluoride (LiF) having a LUMO energy level of −3.0 eV. The cathode includes aluminum (A1).

The hole carriers transport toward a direction to layers having high HOMO energy levels, and electron carriers transport toward a direction to layers having low LUMO energy levels. The hole barrier layer blocks hole carriers from entering the emissive material layer due to a relatively high HOMO energy level of the hole barrier layer. The electron barrier layer blocks electron carriers from entering the emissive material layer due to a relatively low LUMO level of the electron barrier layer. Upon application of an electric field, hole carriers overcome the energy level barrier and are injected from the anode into the hole injection layer. The hole carriers are then transported from the hole injection layer into the hole transport layer. Electron carriers overcome the energy level barrier and are injected from the cathode into the electron injection layer. The electron carriers are then transported from the electron injection layer into the electron transport layer. The hole carriers and the electron carriers are recombined in the emissive material layer to emit light.

In the exemplary emitting diode illustrated above, the host material of the emissive material layer has a relatively high T1 energy level (e.g., 2.8 eV), effectively preventing energy back transfer. The energy transfer efficiency between the host and the guest (the emissive material according to the present disclosure) is relatively high. The photoluminescence spectrum of the host (mCPBC) shows deep blue emission centered at 446 nm in toluene solution. The larger the overlapping area between the photoluminescence spectrum of the host and the absorption peak of the guest, the higher the energy transfer efficiency. In addition, the guest (the emissive material according to the present disclosure) has a high photoluminescence quantum yield.

In one particular example, the ITO/HATCN layers have a thickness of 10 nm, the NPB layer has a thickness of 30 nm, the BCzPh layer has a thickness of 10 nm, the emissive material layer has a thickness of 20 nm, the CzPhPy layer has a thickness of 10 nm, the DPPyA layer has a thickness of 30 nm, the LiF layer has a thickness of 0.5 nm, and the A1 layer has a thickness of 150 nm. The emissive material layer includes 5 wt % of the guest doped in host. Table 1 lists parameters of several exemplary light-emitting diodes.

TABLE 1
Parameters of several exemplary light-emitting
diodes according to the present disclosure.

| | Vₒₙ | λ_{EL} | CEₘₐₓ | PEₘₐₓ | EQEₘₐₓ | EQE@1000 nit | FWHM |
|---|---|---|---|---|---|---|---|
| Device | (V) | (nm) | (cd/A) | (lm/W) | (%) | (%) | (nm) |
| Example | 3.2 | 598 nm | 64.8 | 76.3 | 29.8 | 20.1 | 34 |
| 1 | | | | | | | |
| Example | 3.4 | 607 nm | 38.0 | 37.4 | 26.4 | 17.6 | 36 |
| 2 | | | | | | | |
| Example | 3.9 | 628 nm | 26.9 | 23.0 | 21.7 | 14.3 | 39 |
| 3 | | | | | | | |

In another example, the anode of the light-emitting diode includes indium tin oxide ITO with a lowest unoccupied molecular orbital (LUMO) energy level of −5.1 eV. The hole injection layer includes 1,4,5,8,9,11-hexaazatriphenylene hexacarbonitrile (HATCN) having a LUMO energy level of −5.5 eV and a highest occupied molecular orbital (HOMO) energy level of −9.5 ev. The hole transport layer includes 4,4′-cyclohexene [N,N-bis(4-methylphenyl)benzenamine](TAPC) having a LUMO energy level of −2.0 eV and a HOMO energy level of −5.5 eV. The electron barrier layer includes 1,3-di(9H-carbazol-9-yl)benzene (mCP) having a LUMO energy level of −2.4 eV and a HOMO energy level of −5.9 eV. The emissive material layer includes 3,3′-Di(9H-carbazol-9-yl)-1,1′-biphenyl (mCBP, host) doped with an emitter (the emissive material according to the present disclosure, guest), having a LUMO energy level of −2.4 eV and a HOMO energy level of −6.0 eV. The electron transport layer includes 1,3,5-Tris(3-pyridyl-3-phenyl)benzene (TmPyPB) having a LUMO energy level of −2.8 eV and a HOMO energy level of −6.8 eV. The electron injection layer includes lithium fluoride (LiF) having a LUMO energy level of −3.0 eV. The cathode includes aluminum (A1). Table 2 lists parameters of several exemplary light-emitting diodes.

TABLE 2
Parameters of several exemplary light-emitting
diodes according to the present disclosure.

| | Vₒₙ | λ_{EL} | CEₘₐₓ | PEₘₐₓ | EQEₘₐₓ | EQE@1000 nit | FWHM |
|---|---|---|---|---|---|---|---|
| Device | (V) | (nm) | (cd/A) | (lm/W) | (%) | (%) | (nm) |
| Example | 3.4 | 600 nm | 65.7 | 78.4 | 27.4 | 21.5 | 36 |
| 4 | | | | | | | |
| Example | 3.5 | 605 nm | 39.2 | 39.2 | 23.2 | 14.7 | 37 |
| 5 | | | | | | | |
| Example | 3.7 | 630 nm | 28.6 | 25.4 | 22.4 | 15.4 | 40 |
| 6 | | | | | | | |

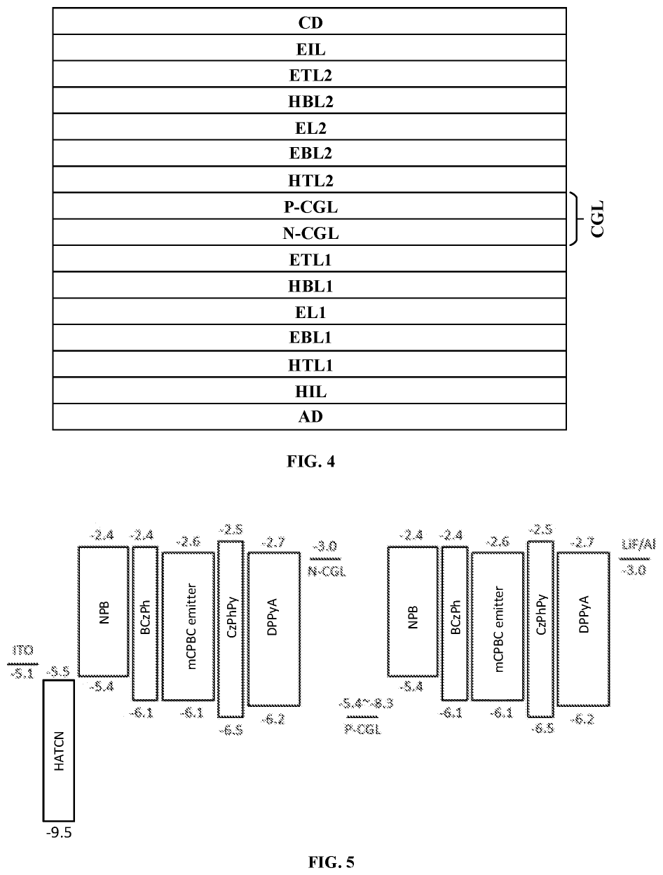

In some embodiments, the present disclosure provides a tandem light-emitting diode. FIG. 4 is a schematic diagram illustrating the structure of a tandem light-emitting diode in some embodiments according to the present disclosure. Referring to FIG. 4, the light-emitting diode in some embodiments includes an anode AD, a hole injection layer HIL on the anode AD, a first hole transport layer HTL1 on a side of the hole injection layer HIL away from the anode AD, a first electron barrier layer EBL1 on a side of the first hole transport layer HTL1 away from the hole injection layer HIL, a first emissive material layer EL1 on a side of the first electron barrier layer EBL1 away from the first hole transport layer HTL1, a first hole barrier layer HBL1 on a side of the first emissive material layer EL1 away from the first electron barrier layer EBL1, a first electron transport layer ETL1 on a side of the first hole barrier layer HBL1 away from the first emissive material layer EL1, a charge generating layer CGL on a side of the first electron transport layer ETL1 away from the first hole barrier layer HBL1, a second hole transport layer HTL2 on a side of the charge generating layer CGL away from the first electron transport layer ETL1, a second electron barrier layer EBL2 on a side of the second hole transport layer HTL2 away from the charge generating layer CGL, a second emissive material layer EL2 on a side of the second electron barrier layer EBL2 away from the second hole transport layer HTL2, a second hole barrier layer HBL2 on a side of the second emissive material layer EL2 away from the second electron barrier layer EBL2, a second electron transport layer ETL2 on a side of the second hole barrier layer HBL2 away from the second emissive material layer EL2, an electron injection layer EIL on a side of the second electron transport layer ETL2 away from the second hole barrier layer HBL2, and a cathode CD on a side of the electron injection layer EIL away from the second electron transport layer ETL2.

In some embodiments, the charge generating layer CGL includes a n-doped layer N-CGL and a p-doped layer P-CGL on a side of the n-doped layer N-CGL away from the first electron transport layer ETL1. The n-doped layer N-CGL and the p-doped layer P-CGL are directly connected to one another, forming a pn junction. In the pn junction, a depletion region is formed, in which electrons of the n-doped layer N-CGL migrate into the p-doped layer P-CGL.

Various appropriate n-doped materials may be used for making the n-doped layer N-CGL. Various appropriate p-doped materials may be used for making the p-doped layer P-CGL. The n-doped layer N-CGL and the p-doped layer P-CGL may include one or more organic and/or inorganic material(s) as matrix. The matrix is admixed with one or more organic or inorganic dopants to increase the conductivity of the matrix. Examples of dopants for the n-doped layer N-CGL include metals having a low work function, e.g. Na, Ca, Cs, Li, Mg or compounds thereof e.g. Cs₂CO₃, Cs₃PO₄, or organic dopants such as NDN-1, NDN-26. Examples of dopants for p-doped layer P-CGL include transition metal oxides, e.g., MoOx, WOx, VOx, organic compounds, e.g., Cu(I)pFBz, F4-TCNQ, or organic dopants such as NDP-2, NDP-9.

FIG. 5 is a schematic diagram illustrating the structure of a tandem light-emitting diode in some embodiments according to the present disclosure. Referring to FIG. 5, the anode of the light-emitting diode includes indium tin oxide ITO with a LUMO energy level of −5.1 eV. The hole injection layer includes 1,4,5,8,9,11-hexaazatriphenylene hexacarbonitrile (HATCN) having a LUMO energy level of −5.5 eV and a HOMO energy level of −9.5 eV. The first hole transport layer and the second hole transport layer include N,N′-diphenyl-N,N′-(1-naphthyl)-1,1′-biphenyl-4,4′-diamine (NPB) having a LUMO energy level of −2.4 eV and a HOMO energy level of −5.4 eV. The first electron barrier layer and the second electron barrier layer include 9,9′-diphenyl-9H,9′H-3,3′-bicarbazole (BCzPh) having a LUMO energy level of −2.4 eV and a HOMO energy level of −6.1 eV. The first emissive material layer and the second emissive material layer include 9-(3-(9H-carbazol-9-yl)phenyl)-9H-3,9′-bicarbazole (mCPBC, host) doped with an emitter (the emissive material according to the present disclosure, guest), having a LUMO energy level of −2.6 eV and a HOMO energy level of −6.1 eV. The first hole barrier layer and the second hole barrier layer include 4,6-bis(3-(9H carbazol-9-yl)phenyl)pyrimidine (CzPhPy) having a LUMO energy level of −2.5 eV and a HOMO energy level of −6.5 eV. The first electron transport layer and the second electron transport layer include 9,10-bis(6-phenylpyridin-3-yl)anthracene (DPPyA) having a LUMO energy level of −2.7 eV and a HOMO energy level of −6.2 eV. The electron injection layer includes lithium fluoride (LiF) having a LUMO energy level of −3.0 eV. The cathode includes aluminum (A1).

The n-doped layer N-CGL includes 2 wt % of Li in 4,7-Diphenyl-1,10-phenanthroline (BPhen) having a LUMO energy level of −3.0 eV and a HOMO energy level of −6.4 eV. The p-doped layer P-CGL includes 10 wt % of 2,3,5,6-Tetrafluoro-7,7,8,8-tetracyanoquinodimethane (F4-TCNQ) in (NPD) having a LUMO energy level of −5.2 eV and a HOMO energy level of −8.3 eV. Table 3 lists parameters of several exemplary light-emitting diodes.

In one example, the light-emitting diode depicted in FIG. 5 is a tandem light-emitting diode of a single color (e.g., a red color).

TABLE 3
Parameters of several exemplary light-emitting
diodes according to the present disclosure.

| | Vₒₙ | λ_{EL} | CEₘₐₓ | PEₘₐₓ | EQEₘₐₓ | EQE@1000 nit | FWHM |
|---|---|---|---|---|---|---|---|
| Device | (V) | (nm) | (cd/A) | (lm/W) | (%) | (%) | (nm) |
| Example | 6.5 | 604 nm | 90.0 | 61.6 | 40.0 | 31.5 | 35 |
| 7 | | | | | | | |
| Example | 7.0 | 617 nm | 50.4 | 33.5 | 34.6 | 27.1 | 35 |
| 8 | | | | | | | |
| Example | 7.9 | 638 nm | 46.5 | 20.9 | 30.4 | 25.3 | 37 |
| 9 | | | | | | | |

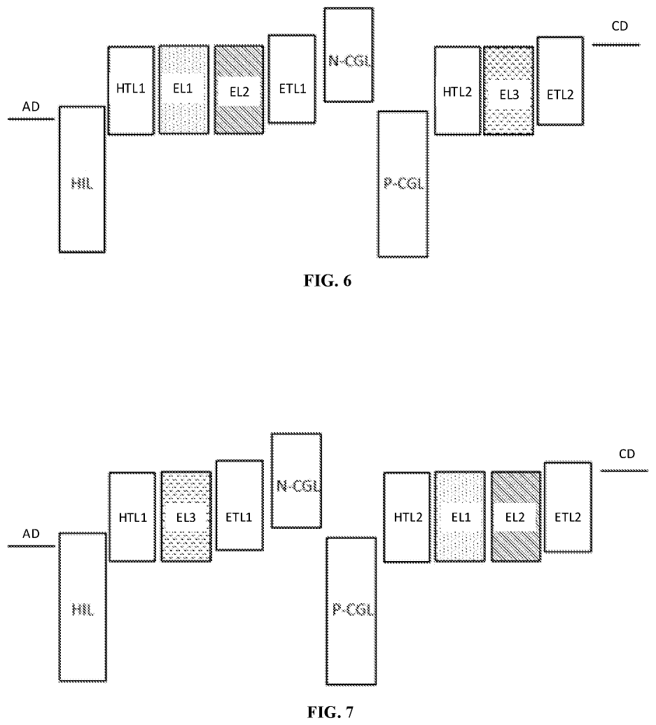

Various appropriate implementations may be practiced in the present disclosure. In some embodiments, the light-emitting diode is a white color tandem light-emitting diode. FIG. 6 is a schematic diagram illustrating the structure of a tandem light-emitting diode in some embodiments according to the present disclosure. Referring to FIG. 6, the light-emitting diode in some embodiments includes an anode AD, a hole injection layer HIL on the anode AD, a first hole transport layer HTL1 on a side of the hole injection layer HIL away from the anode AD, a first emissive material layer EL1 on a side of the first hole transport layer HTL1 away from the hole injection layer HIL, a second emissive material layer EL2 on a side of the first emissive material layer EL1 away from the first hole transport layer HTL1, a first electron transport layer ETL1 on a side of the second emissive material layer EL2 away from the first emissive material layer EL1, an n-doped layer N-CGL on a side of the first electron transport layer ETL1 away from the second emissive material layer EL2, a p-doped layer P-CGL on a side of the n-doped layer N-CGL away from the first electron transport layer ETL1, a second hole transport layer HTL2 on a side of the p-doped layer P-CGL away from the n-doped layer N-CGL, a third emissive material layer EL3 on a side of the second hole transport layer HTL2 away from the p-doped layer P-CGL, a second electron transport layer ETL2 on a side of the third emissive material layer EL3 away from the second hole transport layer HTL2, and a cathode CD on a side of the second electron transport layer ETL2 away from the third emissive material layer EL3.

FIG. 7 is a schematic diagram illustrating the structure of a tandem light-emitting diode in some embodiments according to the present disclosure. Referring to FIG. 7, the light-emitting diode in some embodiments includes an anode AD, a hole injection layer HIL on the anode AD, a first hole transport layer HTL1 on a side of the hole injection layer HIL away from the anode AD, a third emissive material layer EL3 on a side of the first hole transport layer HTL1 away from the hole injection layer HIL, a first electron transport layer ETL1 on a side of the third emissive material layer EL3 away from the first hole transport layer HTL1, an n-doped layer N-CGL on a side of the first electron transport layer ETL1 away from the third emissive material layer EL3, a p-doped layer P-CGL on a side of the n-doped layer N-CGL away from the first electron transport layer ETL1, a second hole transport layer HTL2 on a side of the p-doped layer P-CGL away from the n-doped layer N-CGL, a first emissive material layer EL1 on a side of the second hole transport layer HTL2 away from the p-doped layer P-CGL, a second emissive material layer EL2 on a side of the first emissive material layer EL1 away from the second hole transport layer HTL2, a second electron transport layer ETL2 on a side of the second emissive material layer EL2 away from the first emissive material layer EL1, and a cathode CD on a side of the second electron transport layer ETL2 away from the second emissive material layer EL2.

The emissive material layer according to the present disclosure may be implemented as any one of the first emissive material layer EL1, the second emissive material layer EL2, and the third emissive material layer EL3. In one example, the first emissive material layer EL1 is an emissive material layer of a first color, the second emissive material layer EL2 is an emissive material layer of a second color, and the third emissive material layer EL3 is an emissive material layer of a third color. In one example, the first color is a red color, the second color is a green color, and the third color is a blue color. In another example, the light-emitting diode is configured to emit a white light.

In some embodiments, the first emissive material layer EL1 includes an emissive material according to the present disclosure. In some embodiments, the second emissive material layer EL2 includes an emissive material according to the present disclosure. In some embodiments, the third emissive material layer EL3 includes an emissive material according to the present disclosure. In some embodiments, any two or all of the first emissive material layer EL1, the second emissive material layer EL2, and the third emissive material layer EL3 include an emissive material according to the present disclosure (e.g., of different colors, respectively).

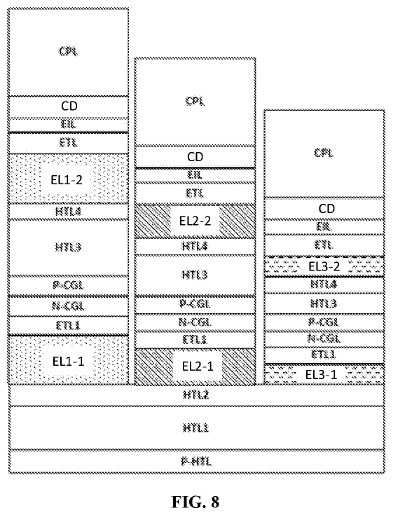

FIG. 8 is a schematic diagram illustrating the structure of a tandem light-emitting diode in some embodiments according to the present disclosure. Referring to FIG. 8, the light-emitting diode in some embodiments includes three individually stacked structures. In some embodiments, the light-emitting diode includes several common layers that are shared by the three individually stacked structures. In some embodiments, the several common layers include a p-type hole transport layer p-HTL, a first hole transport layer HTL1 on the p-type hole transport layer p-HTL, and a second hole transport layer HTL2 on a side of the first hole transport layer HTL1 away from the p-type hole transport layer p-HTL. A first stacked structure in some embodiments further includes a first emissive material layer of a first color EL1-1 on a side of the second hole transport layer HTL2 away from the first hole transport layer HTL1, a first electron transport layer ETL1 on a side of the first emissive material layer of the first color EL1-1 away from the second hole transport layer HTL2, an n-doped layer N-CGL on a side of the first electron transport layer ETL1 away from the first emissive material layer of the first color EL1-1, a p-doped layer P-CGL on a side of the n-doped layer N-CGL away from the first electron transport layer ETL1, a third hole transport layer HTL3 on a side of the p-doped layer P-CGL away from the n-doped layer N-CGL, a fourth hole transport layer HTL4 on a side of the third hole transport layer HTL3 away from the p-doped layer P-CGL, a second emissive material layer of the first color EL1-2 on a side of the fourth hole transport layer HTL4 away from the third hole transport layer HTL3, an electron transport layer ETL on a side of the second emissive material layer of the first color EL1-2 away from the fourth hole transport layer HTL4, an electron injection layer EIL on a side of the electron transport layer ETL away from the second emissive material layer of the first color EL1-2, a cathode CD on a side of the electron injection layer EIL away from the electron transport layer ETL, and a capping layer CPL on a side of the cathode CD away from the electron injection layer EIL.

A second stacked structure in some embodiments further includes a first emissive material layer of a second color EL2-1 on a side of the second hole transport layer HTL2 away from the first hole transport layer HTL1, a first electron transport layer ETL1 on a side of the first emissive material layer of the second color EL2-1 away from the second hole transport layer HTL2, an n-doped layer N-CGL on a side of the first electron transport layer ETL1 away from the first emissive material layer of the second color EL2-1, a p-doped layer P-CGL on a side of the n-doped layer N-CGL away from the first electron transport layer ETL1, a third hole transport layer HTL3 on a side of the p-doped layer P-CGL away from the n-doped layer N-CGL, a fourth hole transport layer HTL4 on a side of the third hole transport layer HTL3 away from the p-doped layer P-CGL, a second emissive material layer of the second color EL2-2 on a side of the fourth hole transport layer HTL4 away from the third hole transport layer HTL3, an electron transport layer ETL on a side of the second emissive material layer of the second color EL2-2 away from the fourth hole transport layer HTL4, an electron injection layer EIL on a side of the electron transport layer ETL away from the second emissive material layer of the second color EL2-2, a cathode CD on a side of the electron injection layer EIL away from the electron transport layer ETL, and a capping layer CPL on a side of the cathode CD away from the electron injection layer EIL.

A third stacked structure in some embodiments further includes a first emissive material layer of a third color EL3-1 on a side of the second hole transport layer HTL2 away from the first hole transport layer HTL1, a first electron transport layer ETL1 on a side of the first emissive material layer of the third color EL3-1 away from the second hole transport layer HTL2, an n-doped layer N-CGL on a side of the first electron transport layer ETL1 away from the first emissive material layer of the third color EL3-1, a p-doped layer P-CGL on a side of the n-doped layer N-CGL away from the first electron transport layer ETL1, a third hole transport layer HTL3 on a side of the p-doped layer P-CGL away from the n-doped layer N-CGL, a fourth hole transport layer HTL4 on a side of the third hole transport layer HTL3 away from the p-doped layer P-CGL, a second emissive material layer of the third color EL3-2 on a side of the fourth hole transport layer HTL4 away from the third hole transport layer HTL3, an electron transport layer ETL on a side of the second emissive material layer of the third color EL3-2 away from the fourth hole transport layer HTL4, an electron injection layer EIL on a side of the electron transport layer ETL away from the second emissive material layer of the third color EL3-2, a cathode CD on a side of the electron injection layer EIL away from the electron transport layer ETL, and a capping layer CPL on a side of the cathode CD away from the electron injection layer EIL.

In one example, the first color is a red color, the second color is a green color, and the third color is a blue color. In another example, the light-emitting diode is configured to emit a white light.

In another aspect, the present disclosure provides a display substrate including the light-emitting diode described herein or fabricated by a method described herein, and a pixel driving circuit configured to drive light emission of the light-emitting diode.

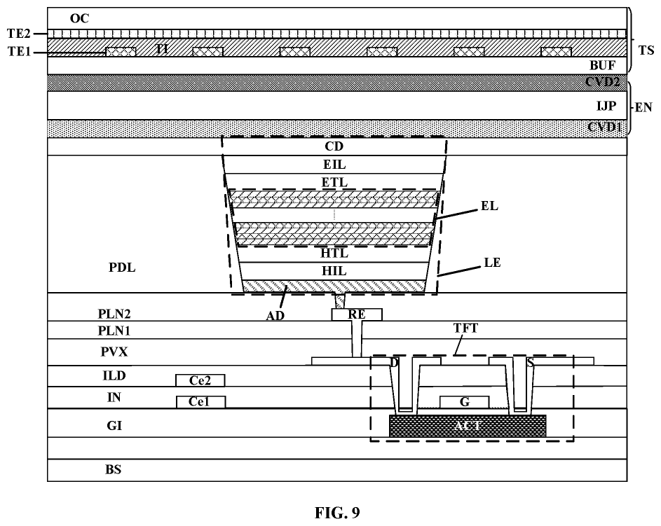

FIG. 9 is a schematic diagram illustrating the structure of a display substrate in some embodiments according to the present disclosure. Referring to FIG. 9, the display substrate in some embodiments includes a base substrate BS; an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a relay electrode RE (part of a second SD metal layer) on side of the first planarization layer PLN1 away from the passivation layer PVX; a second planarization layer PLN2 on a side of the relay electrode RE (part of a second SD metal layer) away from the first planarization layer PLN1; a pixel definition layer PDL defining a subpixel aperture and on a side of the second planarization layer PLN2 away from the base substrate BS; and a light-emitting diode LE in the subpixel aperture. The light-emitting diode LE includes an anode AD on the base substrate BS, a hole injection layer HIL on a side of the anode AD away from the base substrate BS, a hole transport layer HTL on a side of the hole injection layer HIL away from the base substrate BS, an emissive material layer EL on a side of the hole transport layer HTL away from the base substrate BS, an electron transport layer ETL on a side of the emissive material layer EL away from the base substrate BS, an electron injection layer EIL on a side of the electron transport layer ETL away from the base substrate BS, and a cathode CD on a side of the electron injection layer EIL away from the base substrate BS.

The display substrate in the display area further includes an encapsulating layer EN encapsulating the light-emitting element LE, and on a side of the cathode layer CD away from the base substrate BS. The encapsulating layer EN in some embodiments includes a first inorganic encapsulating sub-layer CVD1 on a side of the cathode layer CD away from the base substrate BS, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer JP away from the base substrate BS.

The display substrate in some embodiments further includes a touch structure TS. In some embodiments, the touch structure TS includes a buffer layer BUF on a side of the encapsulating layer EN away from the base substrate BS; a first touch electrode layer TE1 on a side of the buffer layer BUF away from the encapsulating layer EN; a touch insulating layer TI on a side of the first touch electrode layer TE1 away from the buffer layer BUF; a second touch electrode layer TE2 on a side of the touch insulating layer TI away from the buffer layer BUF; and an overcoat layer OC on a side of the second touch electrode layer TE2 away from the touch insulating layer TI.

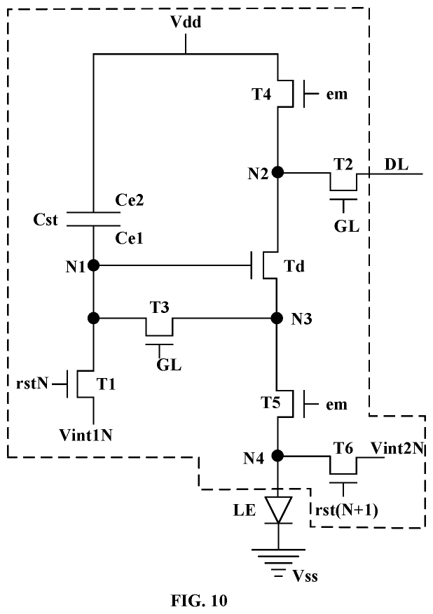

FIG. 10 is a circuit diagram illustrating the structure of a pixel driving circuit in some embodiments according to the present disclosure. Referring to FIG. 10, in some embodiments, the respective pixel driving circuit includes a driving transistor Td; a storage capacitor Cst having a first capacitor electrode Ce1 and a second capacitor electrode Ce2; a first transistor T1 having a gate electrode connected to a respective reset control signal line rstN in a present stage (or a present row) of a plurality of reset control signal lines, a first electrode connected to a respective first reset signal line Vint1N in a present stage (or a present row) of a plurality of first reset signal lines, and a second electrode connected to a first capacitor electrode Ce1 of the storage capacitor Cst and a gate electrode of the driving transistor Td; a second transistor T2 having a gate electrode connected to a respective gate line of a plurality of gate lines GL, a first electrode connected to a respective data line of a plurality of data lines DL, and a second electrode connected to a first electrode of the driving transistor Td; a third transistor T3 having a gate electrode connected to the respective gate line, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor T3, and a second electrode connected to an anode of a light-emitting element LE; and a sixth transistor T6 having a gate electrode connected to a respective reset control signal line rst(N+1) in a next adjacent stage (or a next adjacent row) of a plurality of reset control signal lines, a first electrode connected to a respective second reset signal line Vint2N in the present stage (or the present row) of the plurality of second reset signal lines, and a second electrode connected to the second electrode of the fifth transistor and the anode of the light-emitting element LE. The second capacitor electrode Ce2 is connected to the respective voltage supply line and the first electrode of the fourth transistor T4.

In another aspect, the present disclosure provides a display apparatus including the display substrate described herein or fabricated by a method described herein, and one or more integrated circuits connected to the display substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light-emitting diode display apparatus. Optionally, the display apparatus is a mini light-emitting diode display apparatus. Optionally, the display apparatus is a quantum dot light-emitting diode display apparatus.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light emitting material, having a molecular structure formula of (D)m-(A)q-(D)m′;
wherein D stands for a donor moiety of a molecule of the emissive material configured as an electron donating part of the molecule upon excitation, D being a part of the molecule where at least one occupied orbital of the molecule is distributed;
A stands for an acceptor moiety of the molecule configured as an electron accepting part of the molecule upon excitation, A being a part of the molecule where at least one unoccupied orbital of the molecule is distributed;
m and m′ are positive integers greater than 0; and
q is a positive integer greater than 1.

2. The light emitting material of claim 1, wherein the light emitting material has a molecular structure formula of D1-dA-D2;
D1 stands for a first donor moiety, D2 stands for a second donor moiety;
dA comprises a first acceptor moiety and a second acceptor moiety; and
the first acceptor moiety and the second acceptor moiety are covalently linked to each other.

3. The light emitting material of claim 2, wherein the light emitting material has a molecular structure formula of D1-A1-L-A2-D2;
D1 stands for a first donor moiety;
D2 stands for a second donor moiety;
A1 stands for a first acceptor moiety;
A2 stands for a second acceptor moiety;
L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, or substituted or unsubstituted heteroarylene, and n is an integer equal to or greater than 0.

4. The light emitting material of claim 3, wherein L is a substituted or unsubstituted arylene.

5. The light emitting material of claim 4, wherein L is selected from the group consisting of:

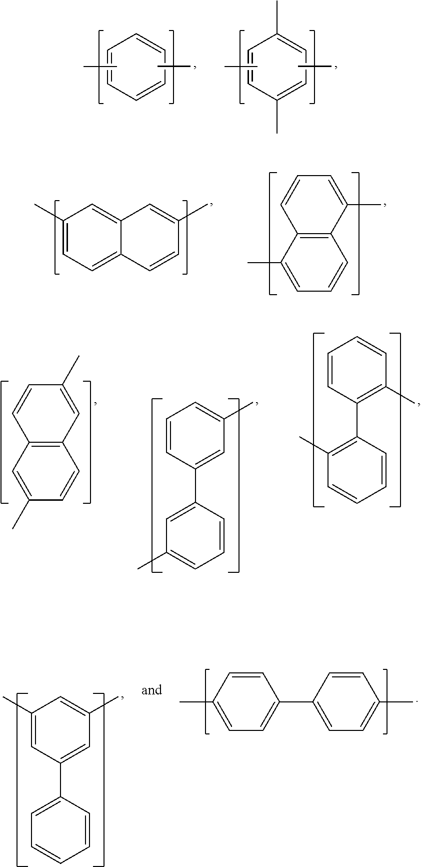

6. The light emitting material of claim 2, wherein the light emitting material has a molecular structure formula of D1-[A1′-cfg-A2′]-D2;
D1 stands for the first donor moiety;
D2 stands for the second donor moiety;
A1′-cfg stands for the first acceptor moiety;
cfg-A2′ stands for the second acceptor moiety; and
the first acceptor moiety and the second acceptor moiety share a common functional group cfg.

7. The light emitting material of claim 6, wherein the common functional group cfg is a functional group comprising a conjugated diene or a conjugated polyene.

8. The light emitting material of claim 2, wherein the first acceptor moiety or the second acceptor moiety comprises a phenanthro-azole moiety.

9. The light emitting material of claim 1, wherein the light emitting material has a molecular structure formula of: 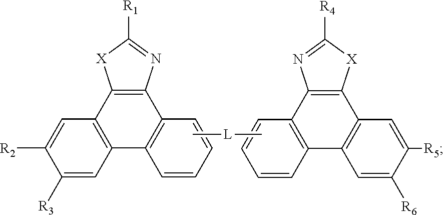
wherein X is —NH—, —O—, —S—, or N—R₀;
R₀, R₁, R₄ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl;
L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, or substituted or unsubstituted heteroarylene;
at least one of R₂ and R₃ is a donor moiety; and
at least one of R₅ and R₆ is a donor moiety.

10. The light emitting material of claim 9, wherein one of R₂ and R₃ is a donor moiety;
the other one of R₂ and R₃ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl;
one of R₅ and R₆ is a donor moiety; and
the other one of R₅ and R₆ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

11. The light emitting material of claim 9, wherein at least one of R₂ and R₃ is a first aromatic amine group; and
at least one of R₅ and R₆ is a second aromatic amine group.

12. The light emitting material of claim 9, wherein the first aromatic amine group and the second aromatic amine group are independently:

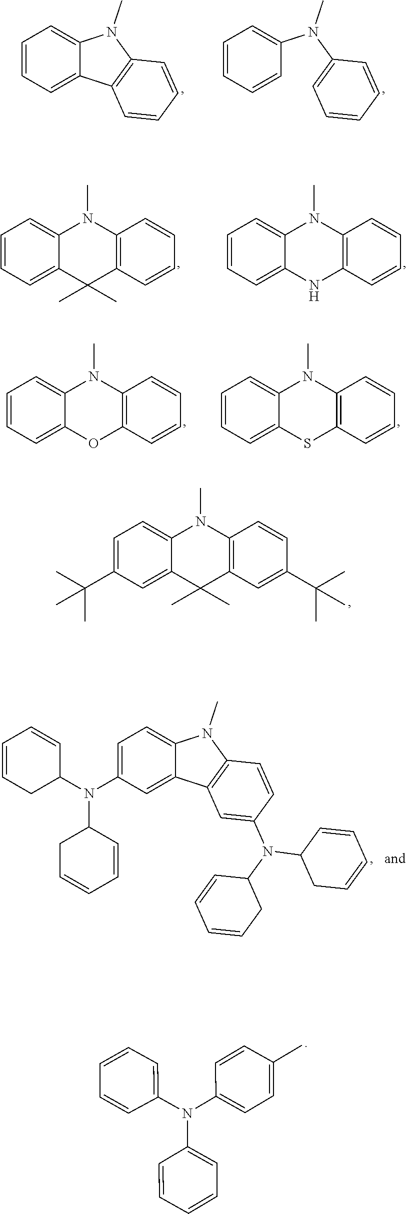

13. The light emitting material of claim 9, wherein L is a single bond; and
the light emitting material has a molecular structure formula of:

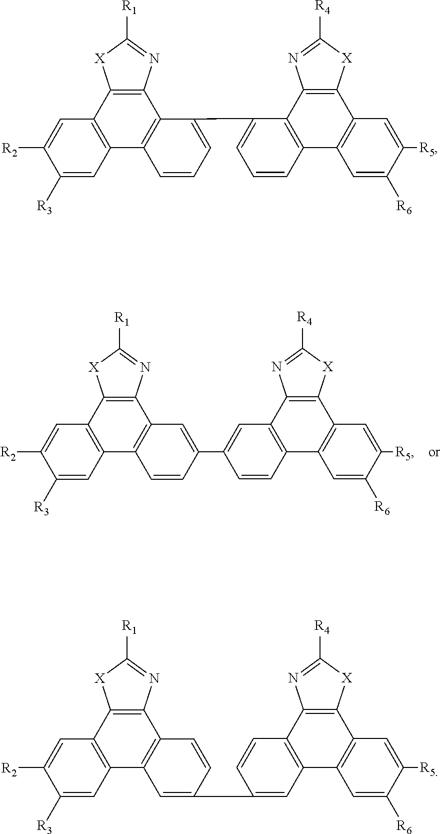

14. The light emitting material of claim 1, wherein the light emitting material has a molecular structure formula of: 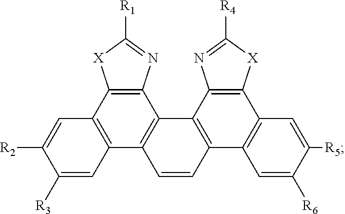
wherein X is —NH—, —O—, —S—, or N—R₀;
R₀, R₁, R₄ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl;
at least one of R₂ and R₃ is a donor moiety; and
at least one of R₅ and R₆ is a donor moiety.

15. The light emitting material of claim 14, wherein one of R₂ and R₃ is a donor moiety;
the other one of R₂ and R₃ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl;
one of R₅ and R₆ is a donor moiety; and
the other one of R₅ and R₆ is hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

16. The light emitting material of claim 14, wherein at least one of R₂ and R₃ is a first aromatic amine group; and
at least one of R₅ and R₆ is a second aromatic amine group.

17. The light emitting material of claim 14, wherein the first aromatic amine group and the second aromatic amine group are independently:

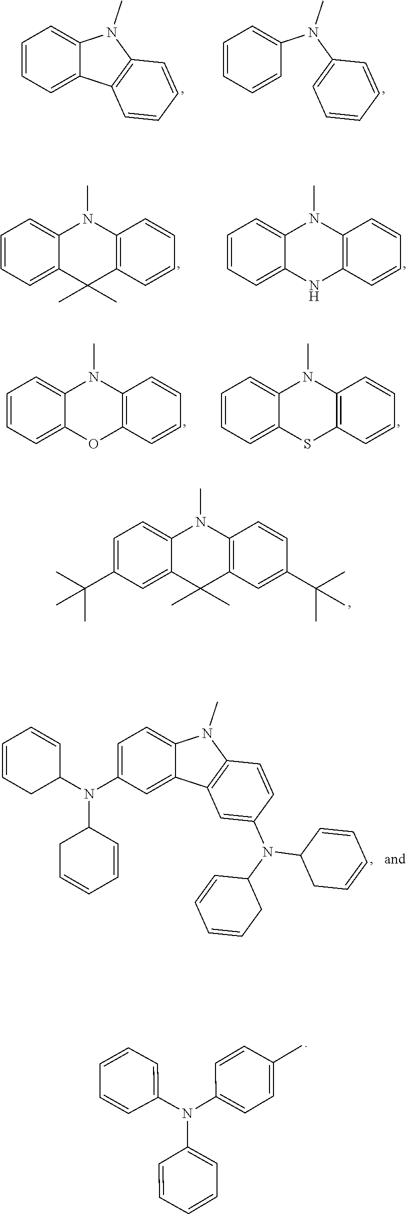

18. The light emitting material of claim 1, wherein the light emitting material is selected from the group consisting of:

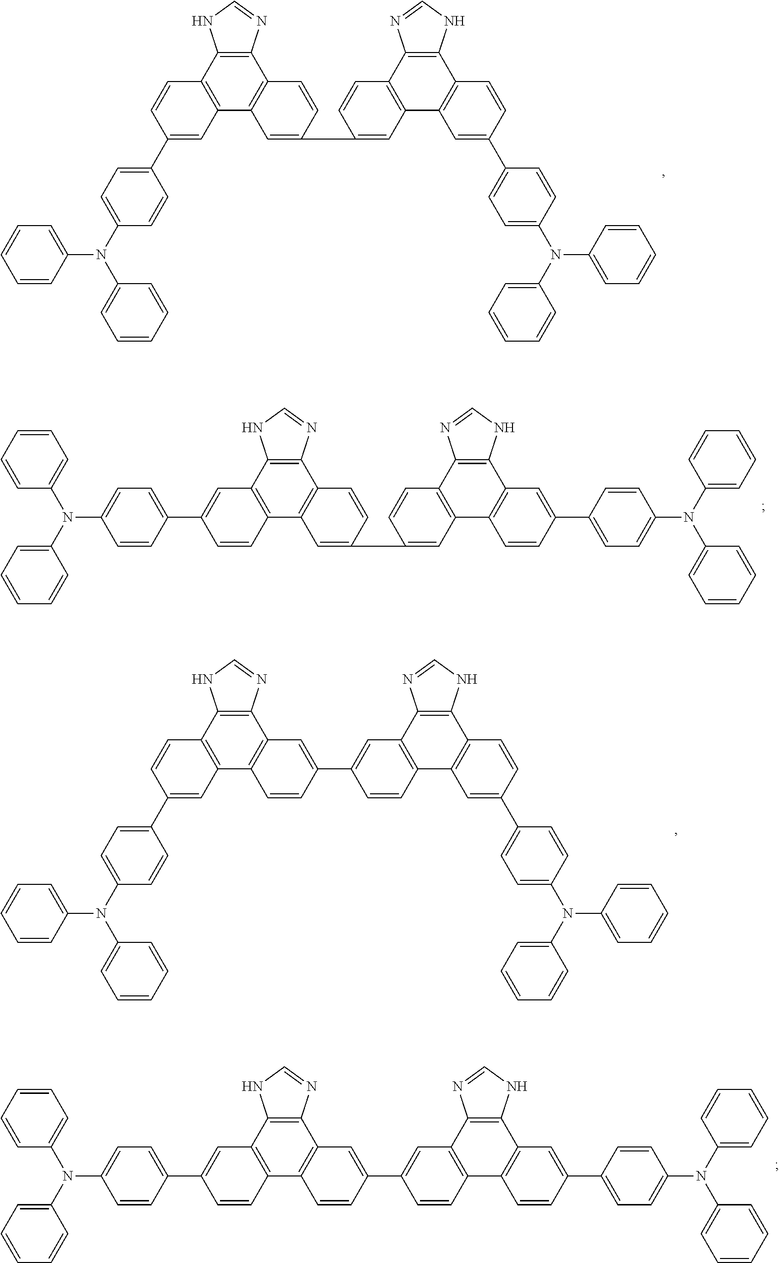

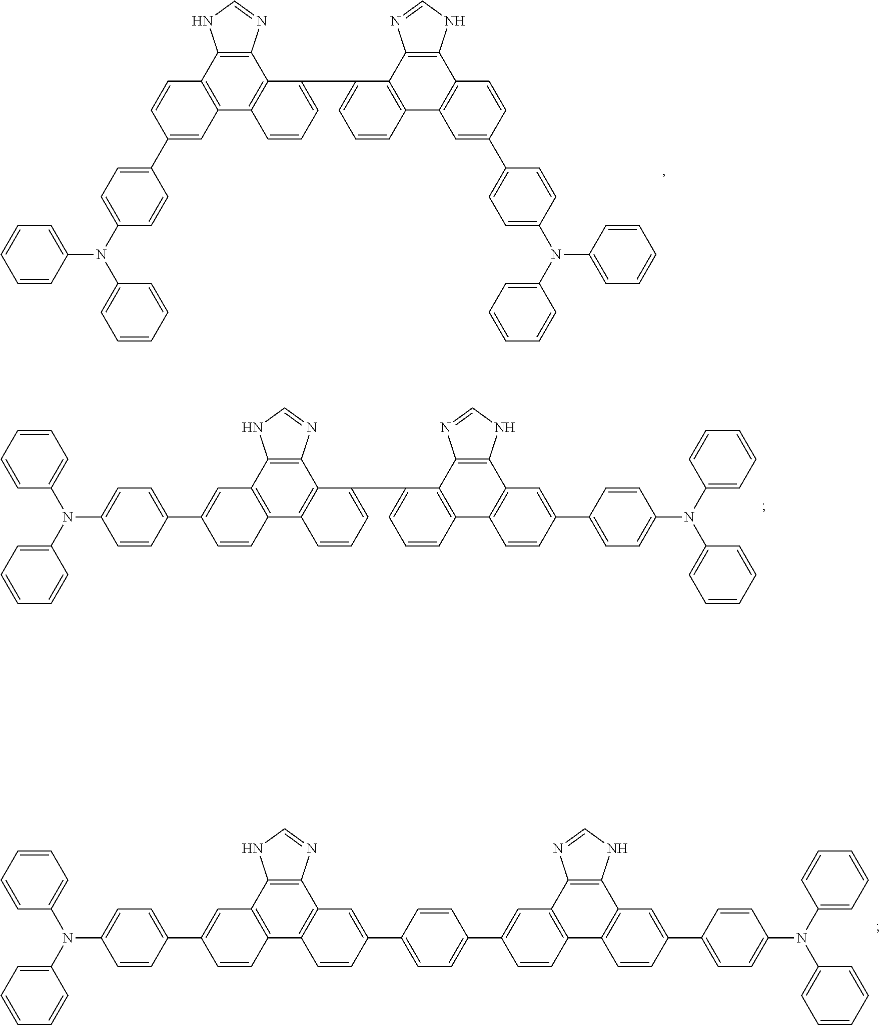 [SMILES: c1ccc(N(c2ccccc2)c2ccc(-c3ccc4c(c3)c3cccc(-c5cccc6c7cc(-c8ccc(N(c9ccccc9)c9ccccc9)cc8)ccc7c7[nH]cnc7c56)c3c3nc[nH]c43)cc2)cc1 ; c1ccc(N(c2ccccc2)c2ccc(-c3ccc4c(c3)c3[nH]cnc3c3c(-c5cccc6c7ccc(-c8ccc(N(c9ccccc9)c9ccccc9)cc8)cc7c7[nH]cnc7c56)cccc43)cc2)cc1 ; c1ccc(N(c2ccccc2)c2ccc(-c3ccc4c5ccc(-c6ccc(-c7ccc8c9ccc(-c%10ccc(N(c%11ccccc%11)c%11ccccc%11)cc%10)cc9c9[nH]cnc9c8c7)cc6)cc5c5nc[nH]c5c4c3)cc2)cc1]

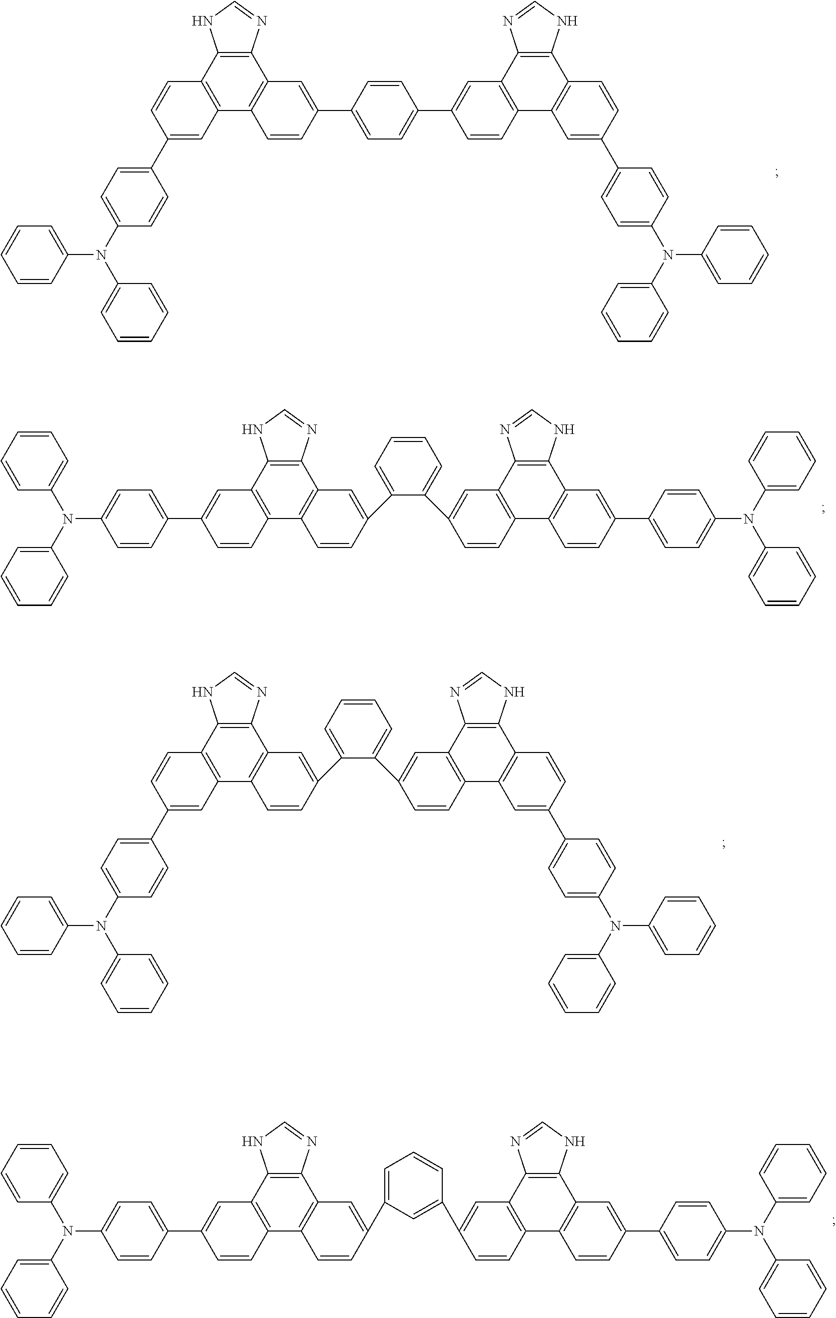

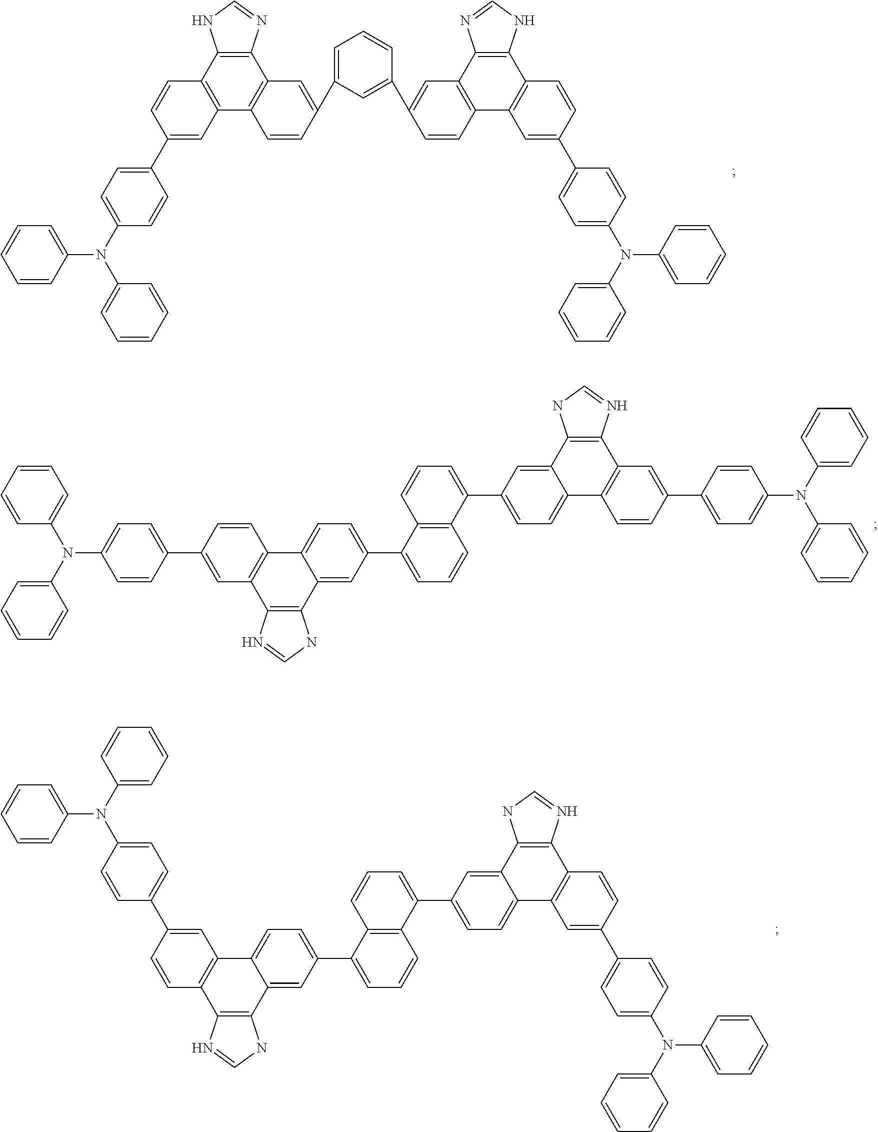

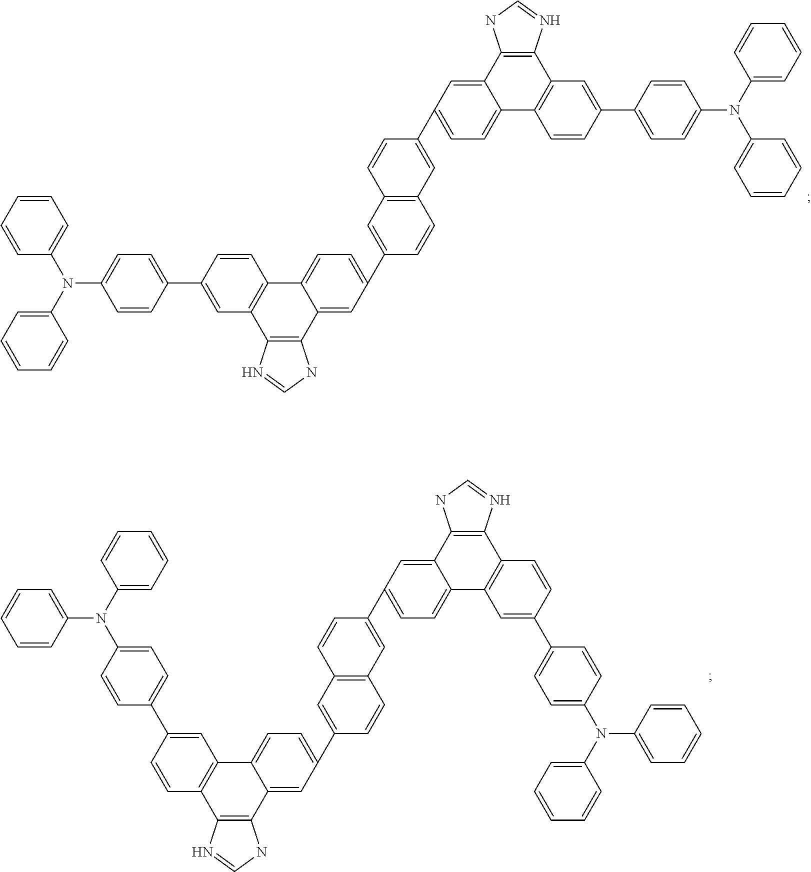 [SMILES: c1ccc(N(c2ccccc2)c2ccc(-c3ccc4c5ccc(-c6ccc7cc(-c8ccc9c%10ccc(-c%11ccc(N(c%12ccccc%12)c%12ccccc%12)cc%11)cc%10c%10nc[nH]c%10c9c8)ccc7c6)cc5c5[nH]cnc5c4c3)cc2)cc1 ; c1ccc(N(c2ccccc2)c2ccc(-c3ccc4c(c3)c3ccc(-c5ccc6cc(-c7ccc8c9cc(-c%10ccc(N(c%11ccccc%11)c%11ccccc%11)cc%10)ccc9c9nc[nH]c9c8c7)ccc6c5)cc3c3[nH]cnc43)cc2)cc1]

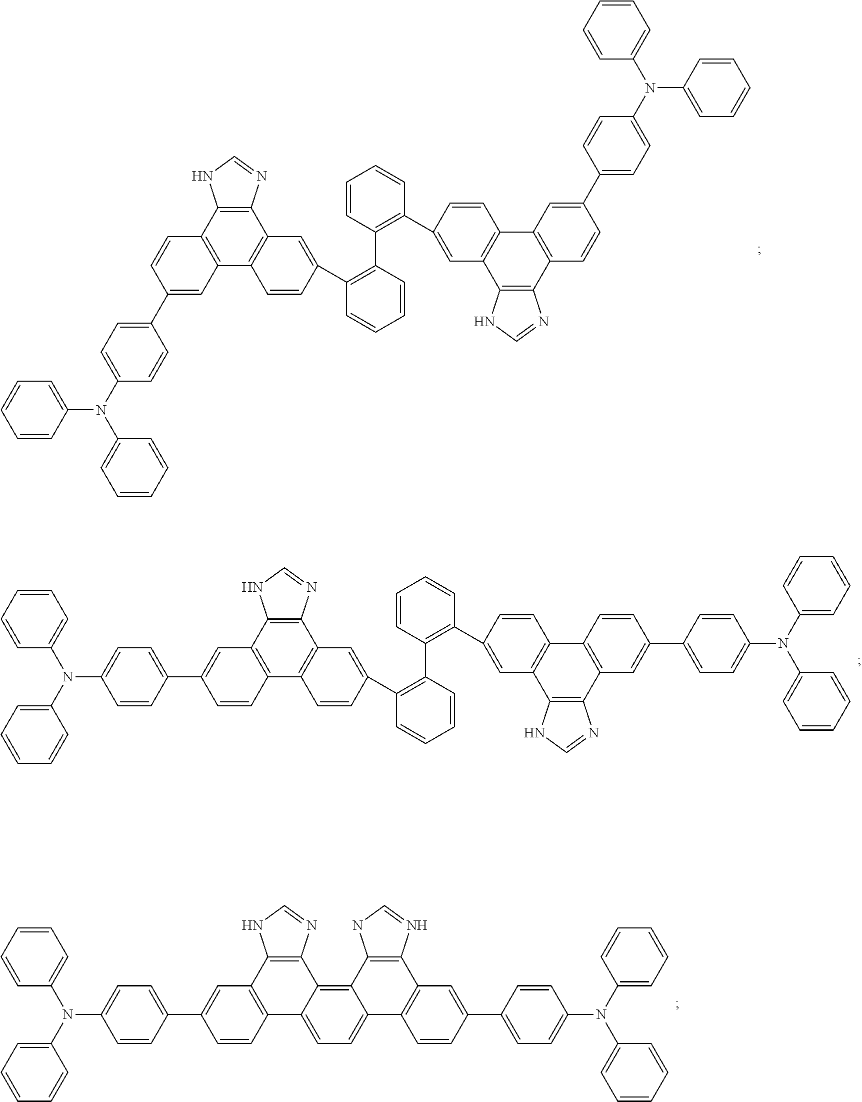 [SMILES: c1ccc(N(c2ccccc2)c2ccc(-c3ccc4c(c3)c3ccc(-c5ccccc5-c5ccccc5-c5ccc6c7cc(-c8ccc(N(c9ccccc9)c9ccccc9)cc8)ccc7c7[nH]cnc7c6c5)cc3c3[nH]cnc43)cc2)cc1 ; c1ccc(N(c2ccccc2)c2ccc(-c3ccc4c5ccc(-c6ccccc6-c6ccccc6-c6ccc7c8ccc(-c9ccc(N(c%10ccccc%10)c%10ccccc%10)cc9)cc8c8[nH]cnc8c7c6)cc5c5[nH]cnc5c4c3)cc2)cc1 ; c1ccc(N(c2ccccc2)c2ccc(-c3ccc4c(c3)c3nc[nH]c3c3c4ccc4c5ccc(-c6ccc(N(c7ccccc7)c7ccccc7)cc6)cc5c5[nH]cnc5c43)cc2)cc1]

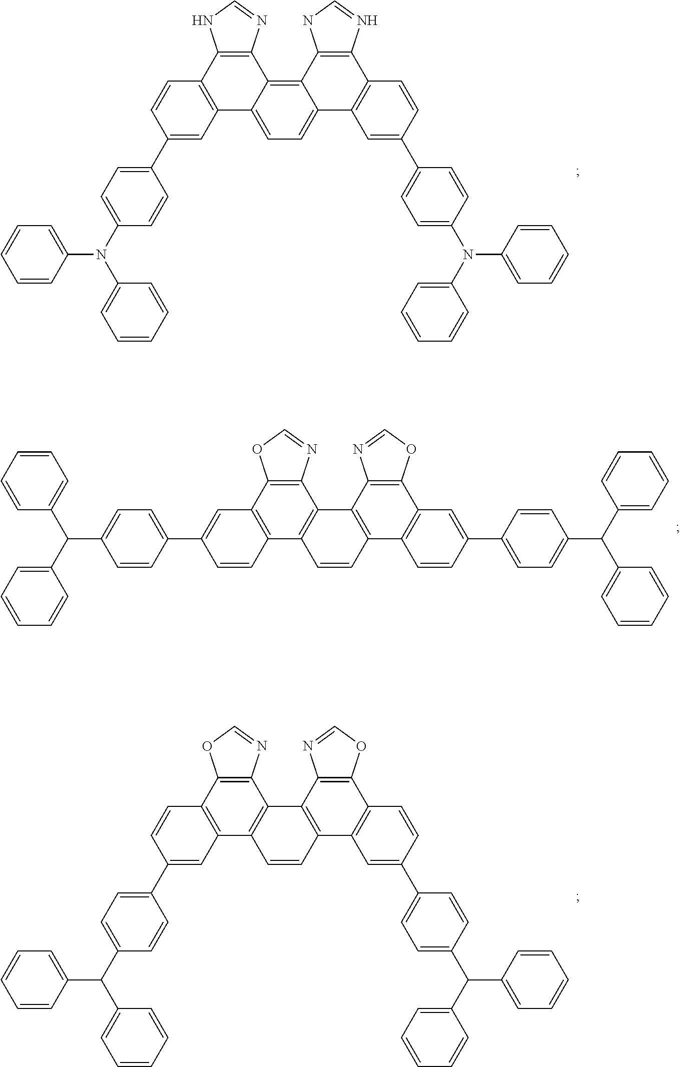 [SMILES: c1ccc(N(c2ccccc2)c2ccc(-c3ccc4c(c3)c3ccc5c6cc(-c7ccc(N(c8ccccc8)c8ccccc8)cc7)ccc6c6nc[nH]c6c5c3c3nc[nH]c43)cc2)cc1 ; c1ccc(C(c2ccccc2)c2ccc(-c3ccc4c(c3)c3ocnc3c3c4ccc4c5ccc(-c6ccc(C(c7ccccc7)c7ccccc7)cc6)cc5c5ocnc5c43)cc2)cc1 ; c1ccc(C(c2ccccc2)c2ccc(-c3ccc4c(c3)c3ccc5c6cc(-c7ccc(C(c8ccccc8)c8ccccc8)cc7)ccc6c6ocnc6c5c3c3ncoc43)cc2)cc1]

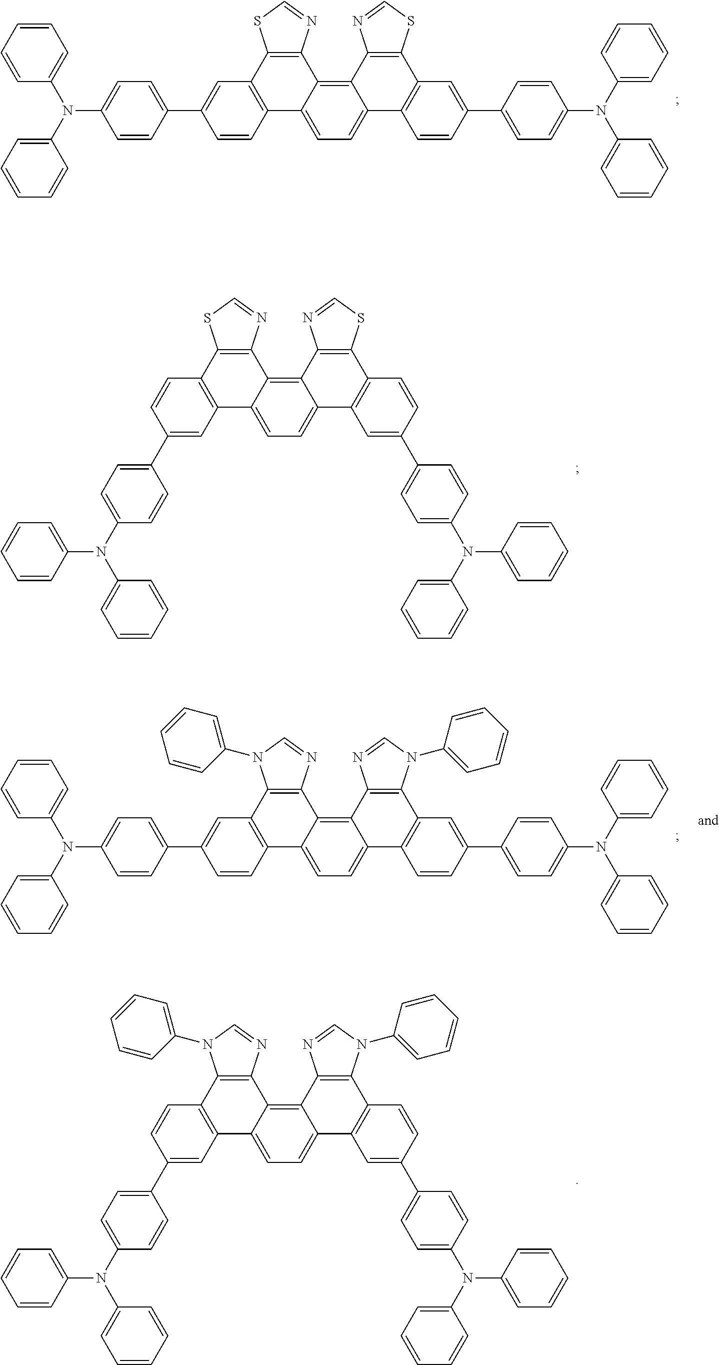 [SMILES: c1ccc(N(c2ccccc2)c2ccc(-c3ccc4c(c3)c3scnc3c3c4ccc4c5ccc(-c6ccc(N(c7ccccc7)c7ccccc7)cc6)cc5c5scnc5c43)cc2)cc1 ; c1ccc(N(c2ccccc2)c2ccc(-c3ccc4c(c3)c3ccc5c6cc(-c7ccc(N(c8ccccc8)c8ccccc8)cc7)ccc6c6scnc6c5c3c3ncsc43)cc2)cc1 ; c1ccc(N(c2ccccc2)c2ccc(-c3ccc4c5ccc6c7ccc(-c8ccc(N(c9ccccc9)c9ccccc9)cc8)cc7c7c(ncn7-c7ccccc7)c6c5c5ncn(-c6ccccc6)c5c4c3)cc2)cc1 ; c1ccc(N(c2ccccc2)c2ccc(-c3ccc4c(c3)c3ccc5c6cc(-c7ccc(N(c8ccccc8)c8ccccc8)cc7)ccc6c6c(ncn6-c6ccccc6)c5c3c3ncn(-c5ccccc5)c43)cc2)cc1]

19. A light emitting diode comprising an anode, a light emitting layer, and a cathode on a side of the light emitting layer away from the anode;
wherein the light emitting layer comprising the light emitting material of claim 1.

20. (canceled)

21. (canceled)

22. A display apparatus, comprising the light emitting diode of claim 19, and a pixel driving circuit configured to drive light emission of the light emitting diode.
